(19) United States
(12) Patent Application Publication
(10) Pub. No.: US 2015/0263298 A1
(43) Pub. Date: Sep. 17, 2015

(54) SILANE COMPOUND AND ORGANIC ELECTROLUMINESCENCE DEVICE`

(71) Applicant: SAMSUNG DISPLAY CO., LTD., Yongin-City (KR)

(72) Inventor: Ichinori TAKADA, Yokohama (JP)

(21) Appl. No.: 14/641,729

(22) Filed: Mar. 9, 2015

(30) Foreign Application Priority Data
Mar. 11, 2014 (JP) 2014-047418

(51) Int. Cl. H01L 51/00; C07F 7/08

(52) U.S. Cl. CPC H01L 51/0094; C07F 7/0818; C07F 7/0814; H01L 51/5012

(57) ABSTRACT

A silane compound is represented by the following Formula 1.

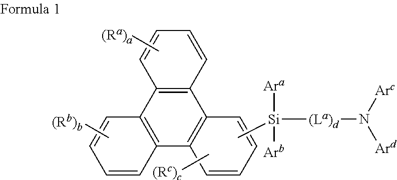

where R^{a}, R^{b}, R^{c}, Ar^{a}, Ar^{b}, Ar^{c}, Ar^{d}, L^{a}, a, b, c, and d are as defined in the specification.

### CROSS-REFERENCE TO RELATED APPLICATION

Japanese Patent Application No. 2014-047418, filed on Mar. 11, 2014, in the Japanese Intellectual Property Office, and entitled: “Silane Compound and Organic Electroluminescence Device,” is incorporated by reference herein in its entirety.

### BACKGROUND

1. Field

Embodiments relate to a silane compound and an organic electroluminescence device.

2. Description of the Related Art

In recent years, organic electroluminescence devices are a type of image display that has been actively developed. In an organic electroluminescence device (hereinafter referred to as an organic EL device), holes and electrons injected from an anode and a cathode, respectively, recombine in an emission layer such that light is emitted from an organic light-emitting material of the emission layer.

### SUMMARY

Embodiments are directed to a silane compound represented by the following Formula 1:

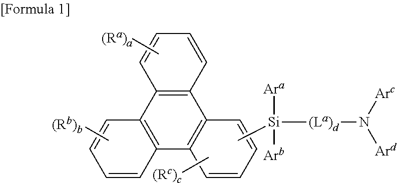

In the above Formula 1, R^{a} to R^{e} are independently a substituted or unsubstituted alkyl group having 1 to 12 carbon atoms or a substituted or unsubstituted aryl group having 4 to 18 carbon atoms, Ar^{a} to Ar^{d} are independently a substituted or unsubstituted aryl group having 6 to 18 carbon atoms or a substituted or unsubstituted heteroaryl group having 5 to 18 carbon atoms, L^{a} is a substituted or unsubstituted arylene group having 6 to 18 carbon atoms, a and b, as subscripts of R^{a} and R^{b}, respectively, are independently an integer from 0 to 4, and c and d, as subscripts of R^{c} and L^{a}, respectively, are independently an integer from 0 to 3.

Ar^{a} and Ar^{b} may be independently a substituted or unsubstituted aryl group having 6 to 13 carbon atoms.

Ar^{a} and Ar^{b} may be independently a substituent selected from a phenyl group, a naphthalenyl group and a biphenylyl group.

The variable d as a subscript of L^{a} may be 0 or 1. L^{a} is a substituted or unsubstituted aryl group having 6 to 13 carbon atoms.

The variables a to c as subscripts of R^{a} to R^{c}, respectively, may be 0 or 1. R^{a} to R^{c} may be independently a substituted or unsubstituted alkyl group having 1 to 6 carbon atoms or a substituted or unsubstituted aryl group having 4 to 12 carbon atoms.

The silane compound may be at least one represented by the following Compounds 1 to 24:

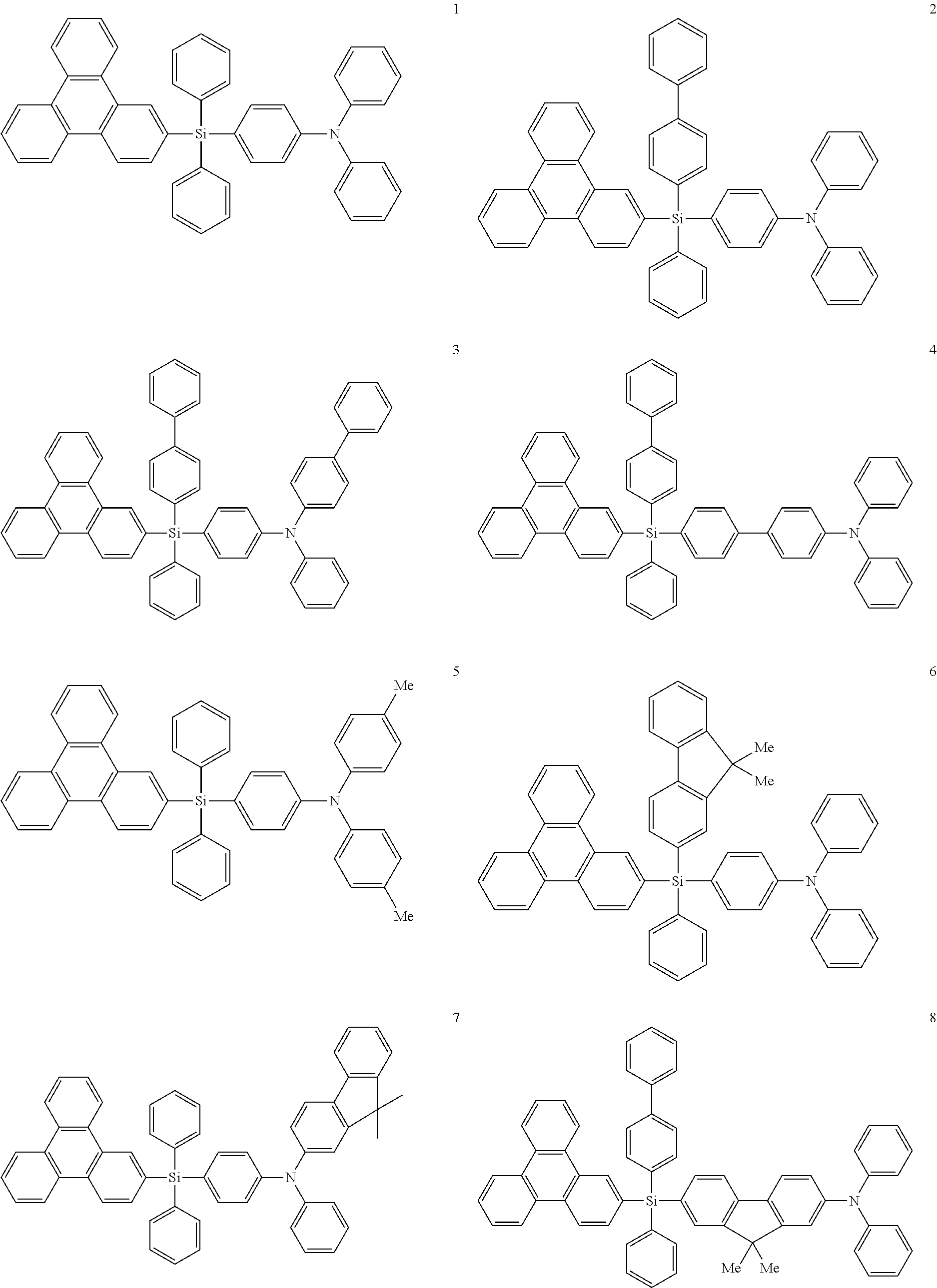

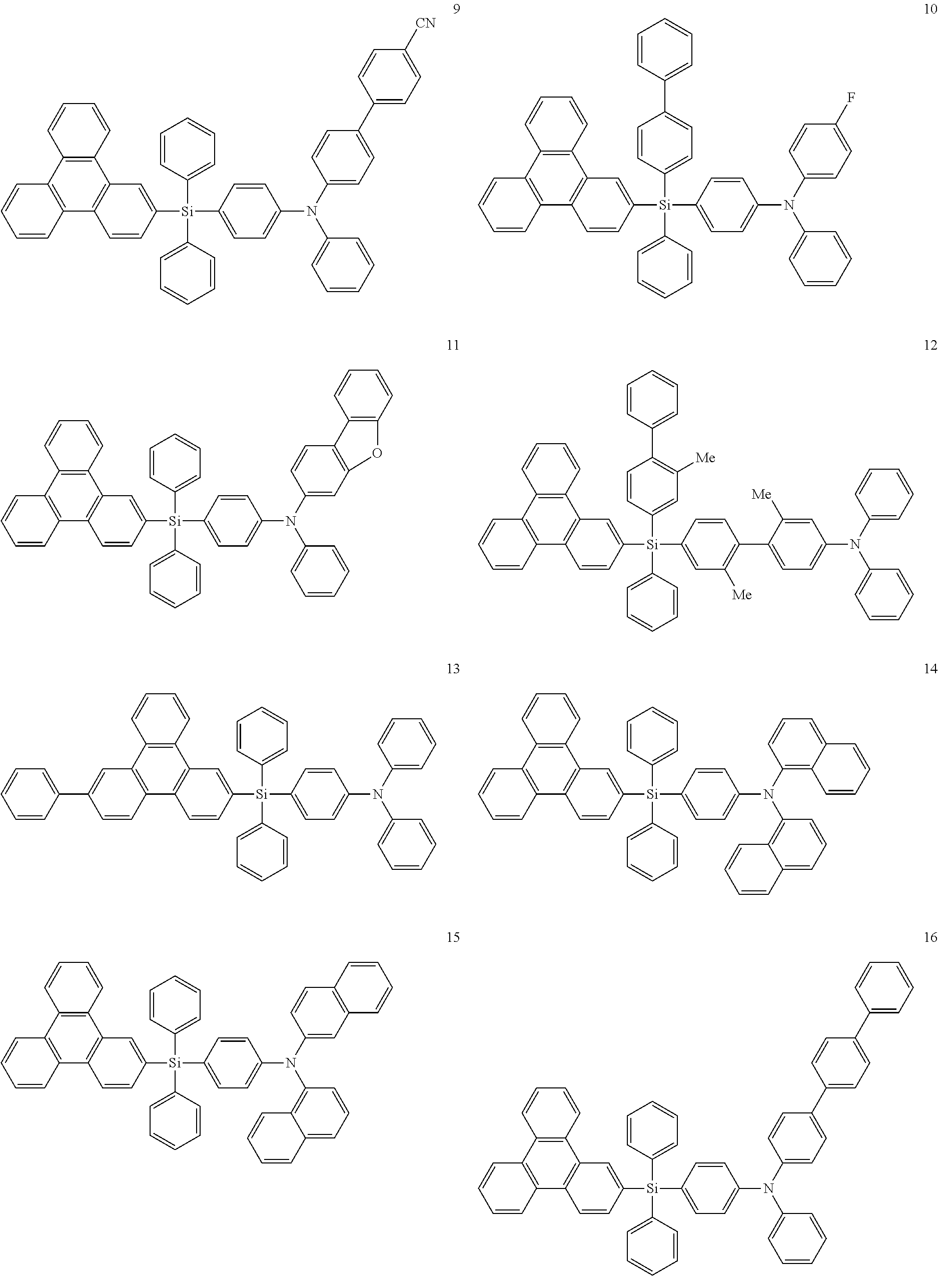

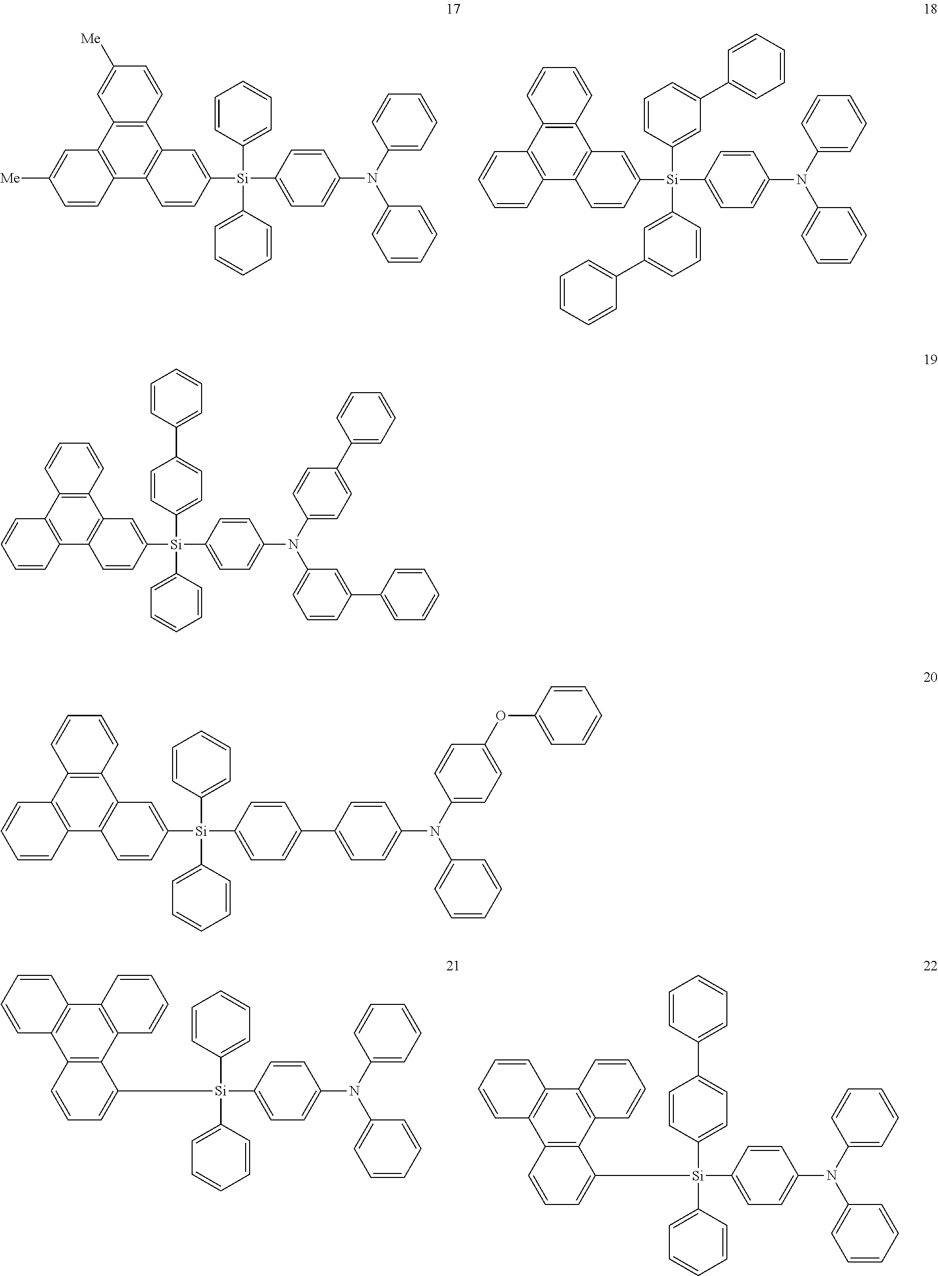

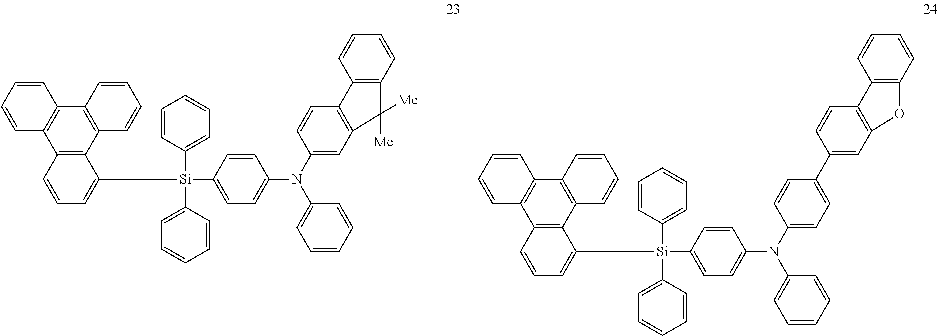 [SMILES: CC1(C)c2ccccc2-c2ccc(N(c3ccccc3)c3ccc([Si](c4ccccc4)(c4ccccc4)c4cccc5c6ccccc6c6ccccc6c45)cc3)cc21 ; c1ccc(N(c2ccc(-c3ccc4c(c3)oc3ccccc34)cc2)c2ccc([Si](c3ccccc3)(c3ccccc3)c3cccc4c5ccccc5c5ccccc5c34)cc2)cc1]

At least one hydrogen of the silane compound may be substituted with one of a methoxy group, a phenoxy group, a cyano group, a trifluoromethyl group and a fluoro group.

Embodiments are also directed to an organic electroluminescence (EL) device including a silane compound in at least one of a layer among organic layers between an anode and an emission layer, and the emission layer. The silane compound is represented by the following Formula 1:

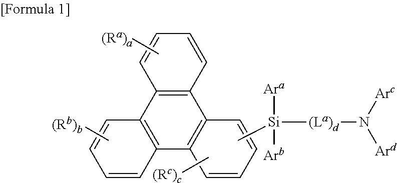

In the above Formula 1, R^{a} to R^{c} are independently a substituted or unsubstituted alkyl group having 1 to 12 carbon atoms or a substituted or unsubstituted aryl group having 4 to 18 carbon atoms, Ar^{a} to Ar^{d} are independently a substituted or unsubstituted aryl group having 6 to 18 carbon atoms or a substituted or unsubstituted heteroaryl group having 5 to 18 carbon atoms, L^{a} is a substituted or unsubstituted arylene group having 6 to 18 carbon atoms, a and b as subscripts of R^{a} and R^{b}, respectively, are independently an integer from 0 to 4, and c and d as subscripts of R^{c} and L^{a}, respectively, are independently an integer from 0 to 3.

Ar^{a} and Ar^{b} may be independently a substituted or unsubstituted aryl group having 6 to 13 carbon atoms.

Ar^{a} and Ar^{b} may be independently a substituent selected from a phenyl group, a naphthalenyl group and a biphenylyl group.

The variable d, as a subscript of L^{a}, may be 0 or 1. L^{a} may be a substituted or unsubstituted aryl group having 6 to 13 carbon atoms.

The variables a to c, as subscripts of R^{a} to R^{e}, respectively, may be 0 or 1. R^{a} to R^{c} may independently be a substituted or unsubstituted alkyl group having 1 to 6 carbon atoms or a substituted or unsubstituted aryl group having 4 to 12 carbon atoms.

The silane compound may be at least one represented by the following Compounds 1 to 24:

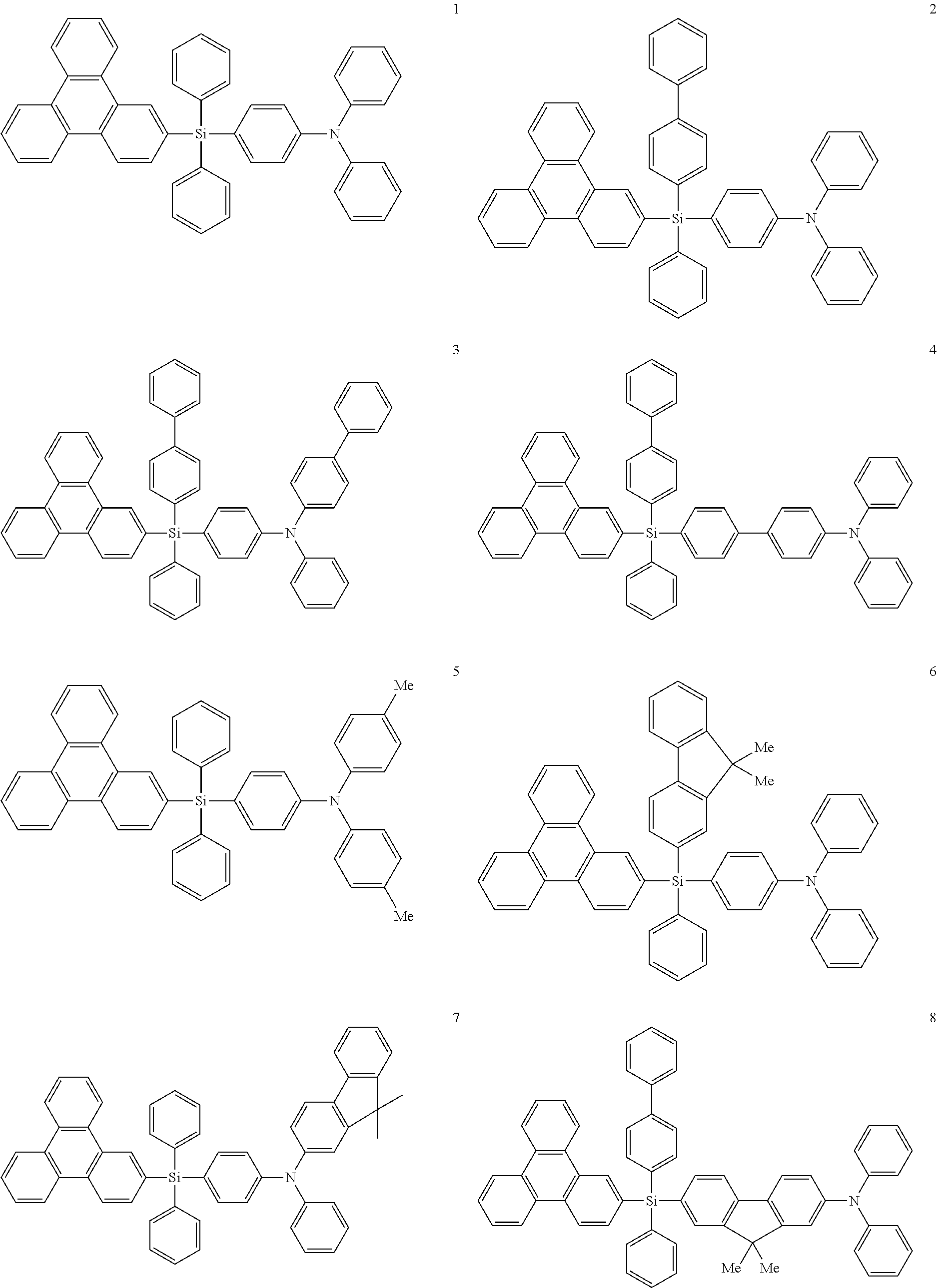

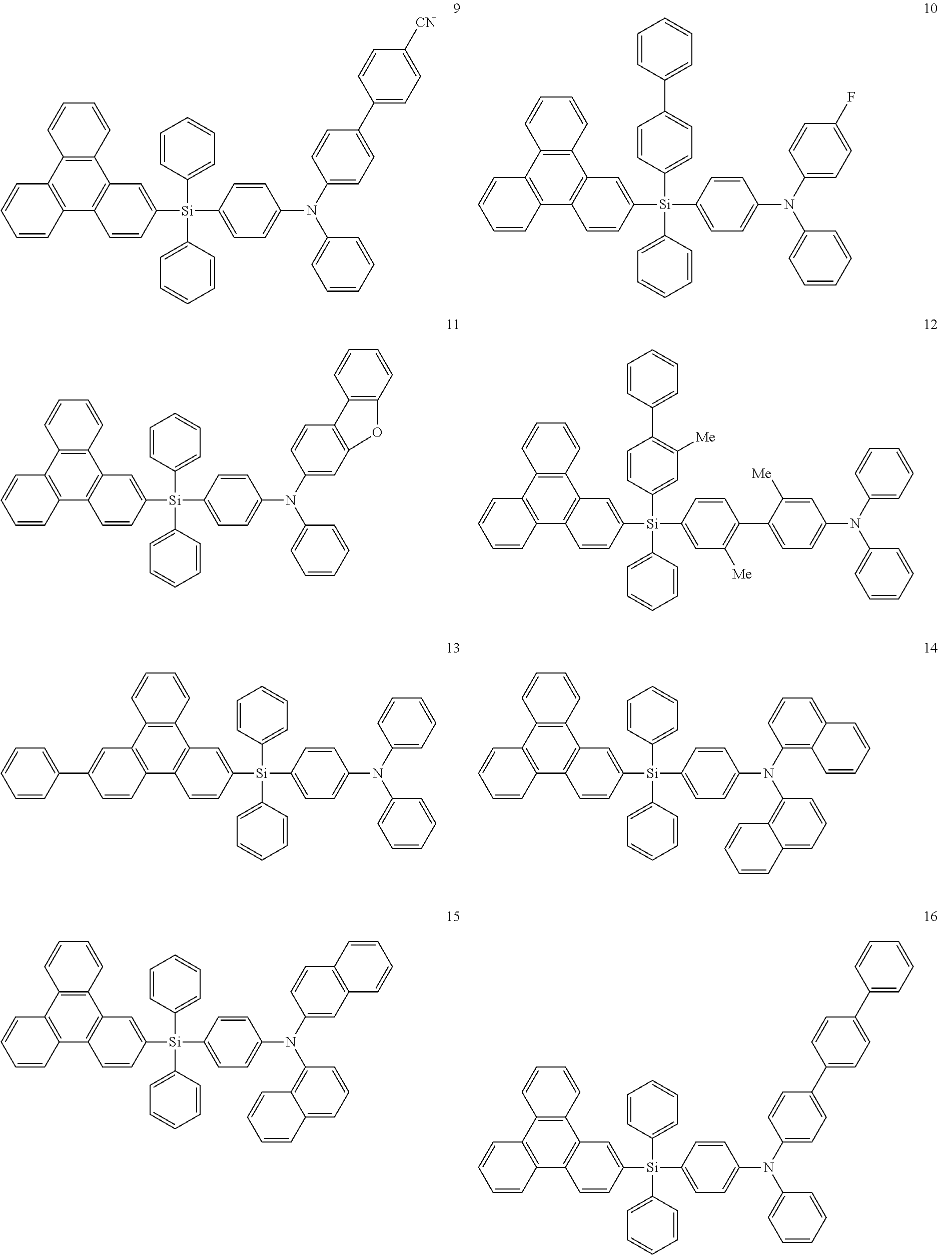

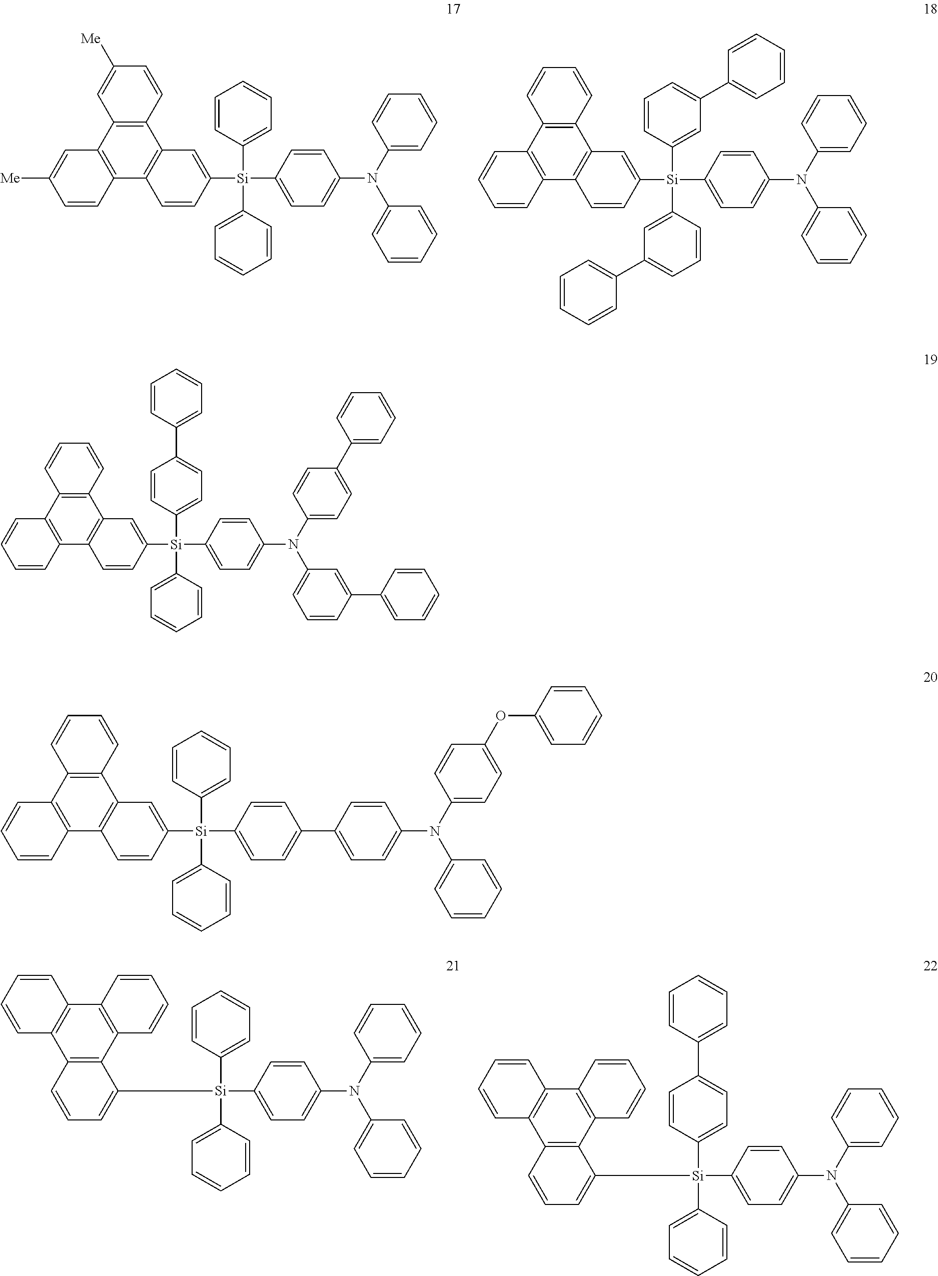

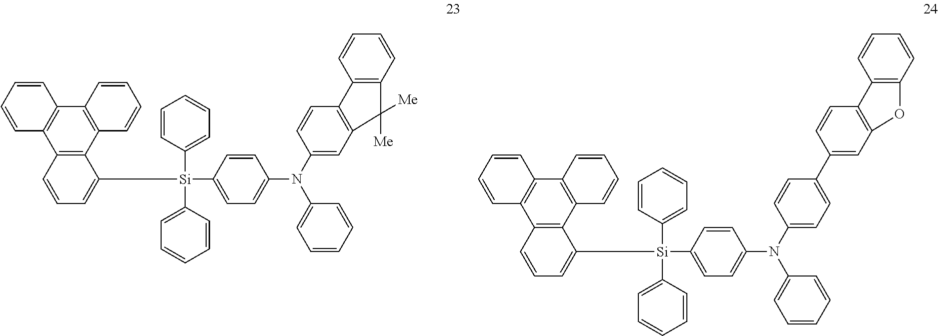 [SMILES: CC1(C)c2ccccc2-c2ccc(N(c3ccccc3)c3ccc([Si](c4ccccc4)(c4ccccc4)c4cccc5c6ccccc6c6ccccc6c45)cc3)cc21 ; c1ccc(N(c2ccc(-c3ccc4c(c3)oc3ccccc34)cc2)c2ccc([Si](c3ccccc3)(c3ccccc3)c3cccc4c5ccccc5c5ccccc5c34)cc2)cc1]

At least one hydrogen of the silane compound may be substituted with one of a methoxy group, a phenoxy group, a cyano group, a trifluoromethyl group and a fluoro group.

### BRIEF DESCRIPTION OF THE DRAWINGS

Features will become apparent to those of skill in the art by describing in detail exemplary embodiments with reference to the attached drawings in which:

FIG. 1 illustrates a schematic cross-sectional view depicting an organic EL device according to an embodiment; and

FIG. 2 illustrates a schematic diagram depicting the structure of an organic EL device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present.

1. Silane Compound According to an Embodiment

A silane compound according to an embodiment is a compound represented by the following Formula 1.

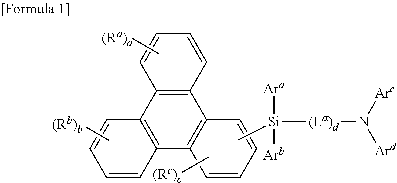

In the above Formula 1,

R^{a} to R^{c} are independently a substituted or unsubstituted alkyl group having 1 to 12 carbon atoms or a substituted or unsubstituted aryl group having 4 to 18 carbon atoms,

Ar^{a} to Ar^{d} are independently a substituted or unsubstituted aryl group having 6 to 18 carbon atoms or a substituted or unsubstituted heteroaryl group having 5 to 18 carbon atoms,

L^{a} is a substituted or unsubstituted arylene group having 6 to 18 carbon atoms,

a and b are independently an integer from 0 to 4, and

c and d are independently an integer from 0 to 3. (Here, a, b, c, and d are the subscripts of R^{a}, R^{b}, R^{c}, and L^{a}, respectively, indicating the number of the respective one of R^{a}, R^{b}, R^{c}, and L^{a} that are present.)

The silane compound represented by the above Formula 1 may include an arylamine group in the molecular structure thereof. The silane compound represented by the above Formula 1 may have hole transport properties and may be appropriately used as a hole transport material in an organic layer positioned between the anode and the emission layer of an organic EL device.

The triplet energy of the silane compound represented by the above Formula 1 may be raised by the triphenylene skeleton. Accordingly, the restraining ability of the diffusion of excited energy may be high such that the silane compound may have a high restraining ability of the diffusion of energy with respect to excited energy generated in an emission layer and may prevent the diffusion of the excited energy to an adjacent layer. In addition, the electron tolerance of the triphenylene skeleton may be high. Accordingly, the silane compound represented by the above Formula 1 may have high electron tolerance with respect to electrons that intrude from an emission layer to an organic layer and may not deteriorate. In addition, a triphenylene group and an aryl group or a heteroaryl group are combined and a silyl group having a sterically large volume. Accordingly, the silane compound represented by the above Formula 1 may have high electron blocking ability with respect to electrons that may intrude from an emission layer to an organic layer and may prevent the transfer of the electrons toward an anode. Therefore, the silane compound represented by Formula 1 and having the above properties may improve the emission properties and/or life of an organic EL device.

A silane compound represented by the above Formula 1 may have a high restraining ability with respect to the diffusion of excited energy. Accordingly, the diffusion of the excited energy from an emission layer may be restrained, and the emission efficiency of an organic EL device may be improved. In addition, the silane compound represented by the above Formula 1 may have high electron tolerance. Accordingly, deterioration due to electrons that intrude from the emission layer may be small. The silane compound may have a high electron blocking ability. Accordingly, further diffusion of electrons that intrude from the emission layer may be prevented. Therefore, the silane compound represented by the above Formula 1 may improve the device life of an organic EL device.

To improve the emission efficiency or device life of an organic EL device, the silane compound represented by the above Formula 3 may be included in at least one layer of organic layers positioned between an emission layer and an anode. For example, the silane compound represented by the above Formula 1 may be included in at least one layer of organic layers such as a hole injection layer and a hole transport layer.

To effectively restrain the diffusion of excited energy from an emission layer and block the intrusion of electrons from the emission layer, the silane compound represented by the above Formula 3 may be included in an organic layer (for example, a hole transport layer) adjacent to the emission layer.

The silane compound represented by the above Formula 1 may be included in an emission layer. The silane compound represented by the above Formula 1 may have a high triplet energy level and high electron tolerance and may be appropriately used as a phosphorescent host material not deteriorated by electrons in an emission layer into which both electrons and holes are injected.

In the above Formula 1, Ar^{a} and Ar^{b} may be independently a substituted or unsubstituted aryl group having 6 to 13 carbon atoms. For example, Ar^{a} and Ar^{b} may be independently one of a phenyl group, a biphenylyl group, and a naphthalenyl group. The silane compound represented by the above Formula 3 may include a triphenylene group having a large volume. Accordingly, Ar^{a} and Ar^{b} may be one of the phenyl group, the biphenylyl group and the naphthalenyl group, which are not functional groups having a large volume, so as to decrease effects due to steric hindrance.

In the above Formula 1, d, representing the number of -L^{a} groups as represented by -(L^{a})_{d}-, may be 0 or 1. L^{a} may be a substituted or unsubstituted aryl group having 6 to 13 carbon atoms, as an example. In addition, in the above Formula 3, a to c, independently representing the number of —R^{a}, — R^{b}, and —R^{c} groups in —(R^{a})ₐ, —(R^{b})_{b} and —(R^{c})_{c}, may be 0 or 1. R^{a} to R^{c} may be independently a substituted or unsubstituted alkyl group having 1 to 6 carbon atoms or a substituted or unsubstituted aryl group having 4 to 12 carbon atoms.

At least one hydrogen in the silane compound represented by the above Formula 1 may be substituted with a methoxy group, a phenoxy group, a cyano group, a trifluoromethyl group or a fluoro group.

In the above Formula 1, the alkyl group may have one of a linear chain, a branched chain and a cyclic shape. Examples of the alkyl group may include, for example, a methyl group, an ethyl group, a propyl group, an isopropyl group, a n-butyl group, a s-butyl group, an isobutyl group, a t-butyl group, a n-pentyl group, a n-hexyl group, a n-heptyl group, a n-octyl group, a cyclopropyl group, a cyclobutyl group, a cyclopentyl group, a cyclohexyl group, a 4-methylcyclohexyl group, a 1-adamantyl group, a 2-adamantyl group, a 1-norbornyl group, a 2-norbornyl group, etc.

In the above Formula 1, examples of the aryl group may include, for example, a phenyl group, a 1-naphthyl group, a 2-naphthyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 2-biphenylyl group, a 3-biphenylyl group, a 4-biphenylyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, a 3-fluoranthenyl group, a 2-fluorenyl group, a 3-fluorenyl group, a 9,9-dimethyl-fluorenyl group, a 9,9-diphenyl-2-fluorenyl group, etc.

In the above Formula 1, examples of the ‘arylene group’ may include a divalent group derived from an aryl group described above.

In the above Formula 1, examples of the heteroaryl group may include, for example, a 1-pyrrolyl group, a 2-pyrrolyl group, a 3-pyrrolyl group, a pyrazinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a quinolyl group, a 3-quinolyl group, a 4-quinolyl group, a 5-quinolyl group, a 6-quinolyl group, a 7-quinolyl group, a 8-quinolyl group, a 1-isoquinolyl group, a 3-isoquinolyl group, a 4-isoquinolyl group, a 5-isoquinolyl group, a 6-isoquinolyl group, a 7-isoquinolyl group, a 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, a 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, a 1,7-phenanthroline-2-yl group, a 1,7-phenanthroline-3-yl group, a 1,7-phenanthroline-4-yl group, a 1,7-phenanthroline-5-yl group, a 1,7-phenanthroline-6-yl group, a 1,7-phenanthroline-8-yl group, a 1,7-phenanthroline-9-yl group, a 1,7-phenanthroline-10-yl group, a 1,8-phenanthroline-2-yl group, a 1,8-phenanthroline-3-yl group, a 1,8-phenanthroline-4-yl group, a 1,8-phenanthroline-5-yl group, a 1,8-phenanthroline-6-yl group, a 1,8-phenanthroline-7-yl group, a 1,8-phenanthroline-9-yl group, a 1,8-phenanthroline-10-yl group, a 1,9-phenanthroline-2-yl group, a 1,9-phenanthroline-3-yl group, a 1,9-phenanthroline-4-yl group, a 1,9-phenanthroline-5-yl group, a 1,9-phenanthroline-6-yl group, a 1,9-phenanthroline-7-yl group, a 1,9-phenanthroline-8-yl group, a 1,9-phenanthroline-10-yl group, a 1,10-phenanthroline-2-yl group, a 1,10-phenanthroline-3-yl group, a 1,10-phenanthroline-4-yl group, a 1,10-phenanthroline-5-yl group, a 2,9-phenanthroline-1-yl group, a 2,9-phenanthroline-3-yl group, a 2,9-phenanthroline-4-yl group, a 2,9-phenanthroline-5-yl group, a 2,9-phenanthroline-6-yl group, a 2,9-phenanthroline-7-yl group, a 2,9-phenanthroline-8-yl group, a 2,9-phenanthroline-10-yl group, a 2,8-phenanthroline-1-yl group, a 2,8-phenanthroline-3-yl group, a 2,8-phenanthroline-4-yl group, a 2,8-phenanthroline-5-yl group, a 2,8-phenanthroline-6-yl group, a 2,8-phenanthroline-7-yl group, a 2,8-phenanthroline-9-yl group, a 2,8-phenanthroline-10-yl group, a 2,7-phenanthroline-1-yl group, a 2,7-phenanthroline-3-yl group, a 2,7-phenanthroline-4-yl group, a 2,7-phenanthroline-5-yl group, a 2,7-phenanthroline-6-yl group, a 2,7-phenanthroline-8-yl group, a 2,7-phenanthroline-9-yl group, a 2,7-phenanthroline-10-yl group, a 1-phenazinyl group, a 2-phenazinyl group, a 1-phenothiazinyl group, a 2-phenothiazinyl group, a 3-phenothiazinyl group, a 4-phenothiazinyl group, a 10-phenothiazinyl group, a 1-phenoxazinyl group, a 2-phenoxazinyl group, a 3-phenoxazinyl group, a 4-phenoxazinyl group, a 10-phenoxazinyl group, a 2-oxazolyl group, a 4-oxazolyl group, a 5-oxazolyl group, a 2-oxadiazolyl group, a 5-oxadiazolyl group, a 3-furazanyl group, a 2-thienyl group, a 3-thienyl group, 1-dibenzofuranyl group, 2-dibenzofuranyl group, 3-dibenzofuranyl group, 4-dibenzofuranyl group, 1-dibenzothiophenyl group, 2-dibenzothiophenyl group, 3-dibenzothiophenyl group, 4-dibenzothiophenyl group, etc.

In addition, examples of the silane compound represented by the above Formula 1 may include the Compounds 1 to 24.

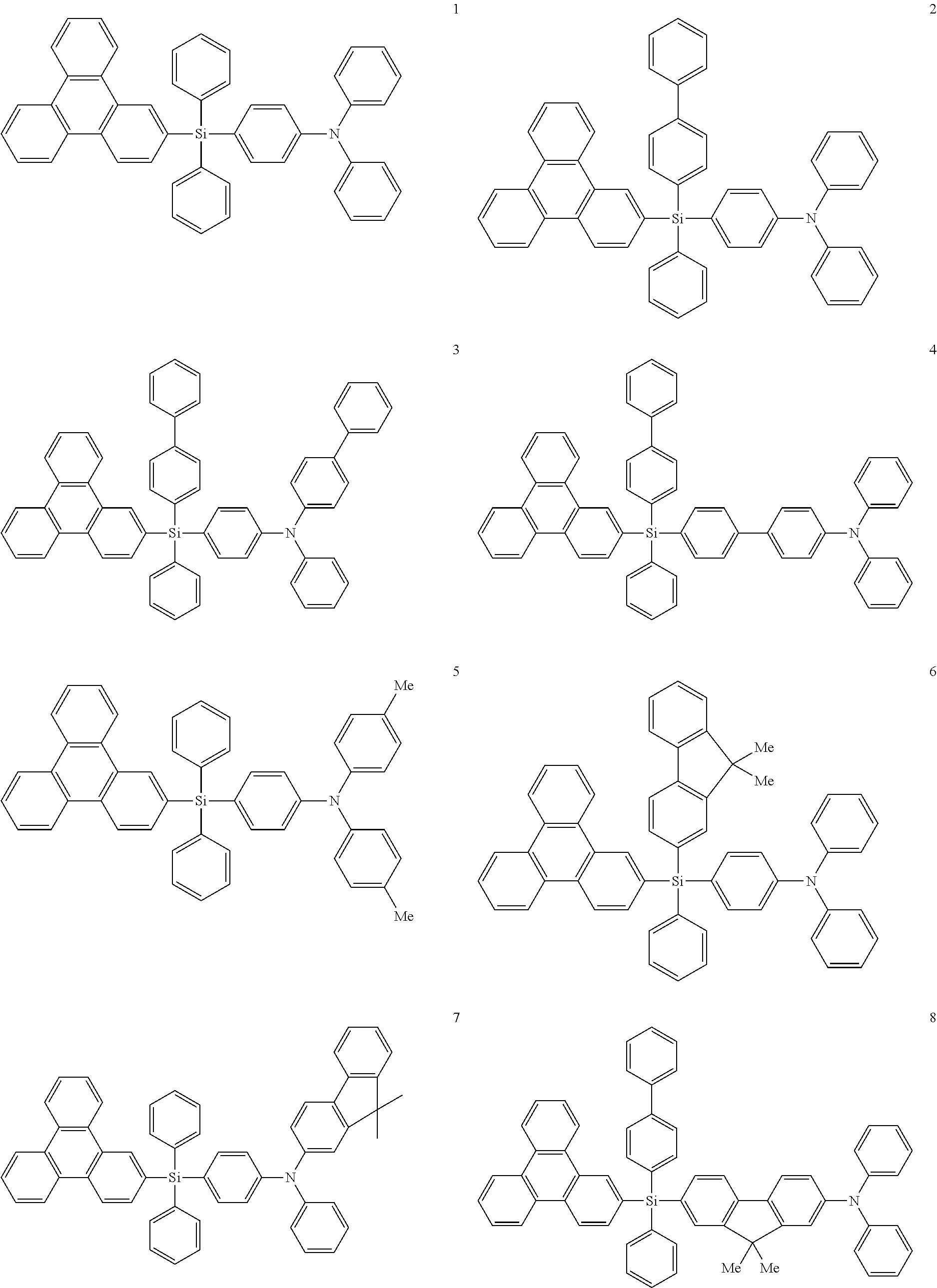

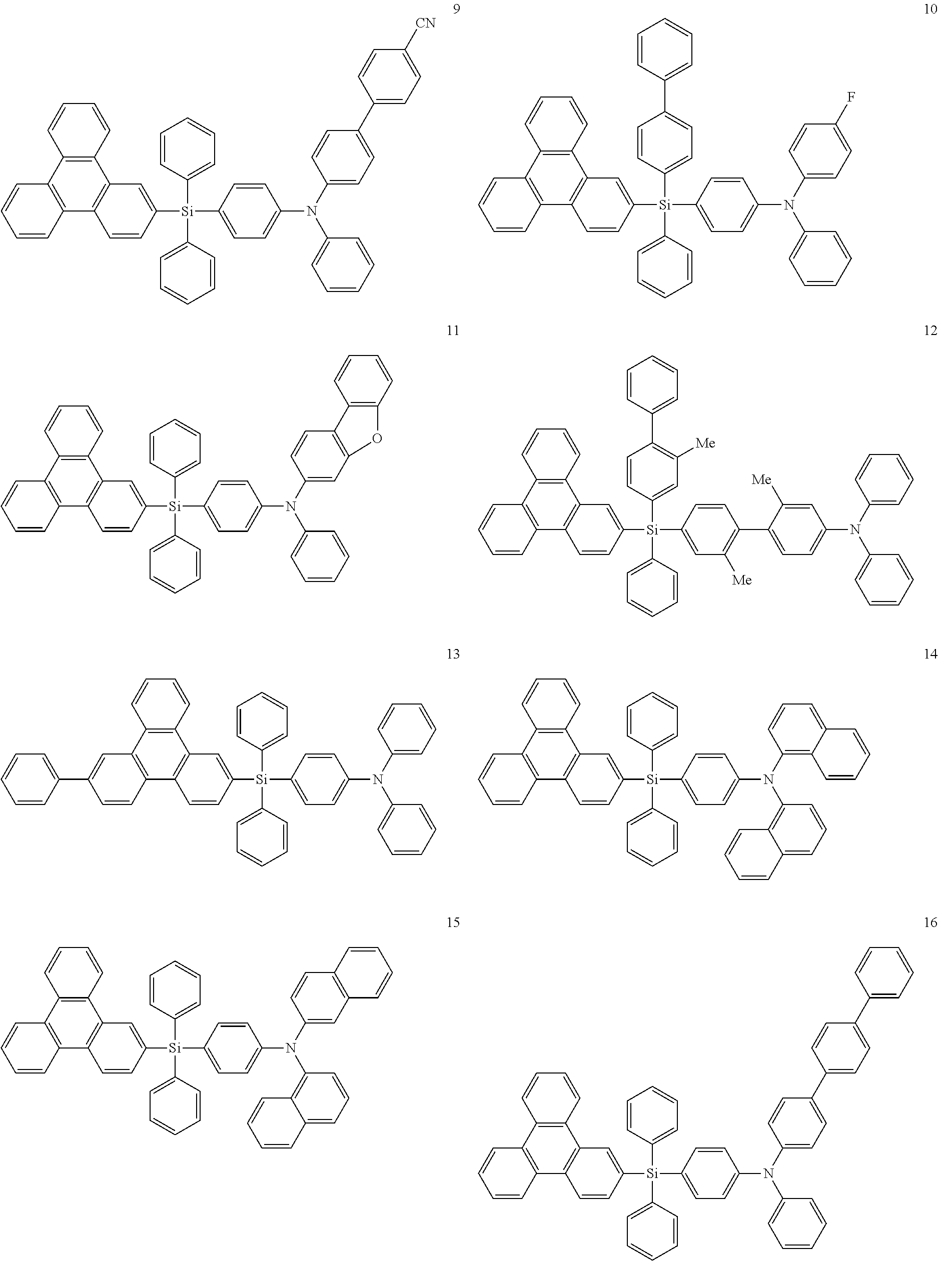

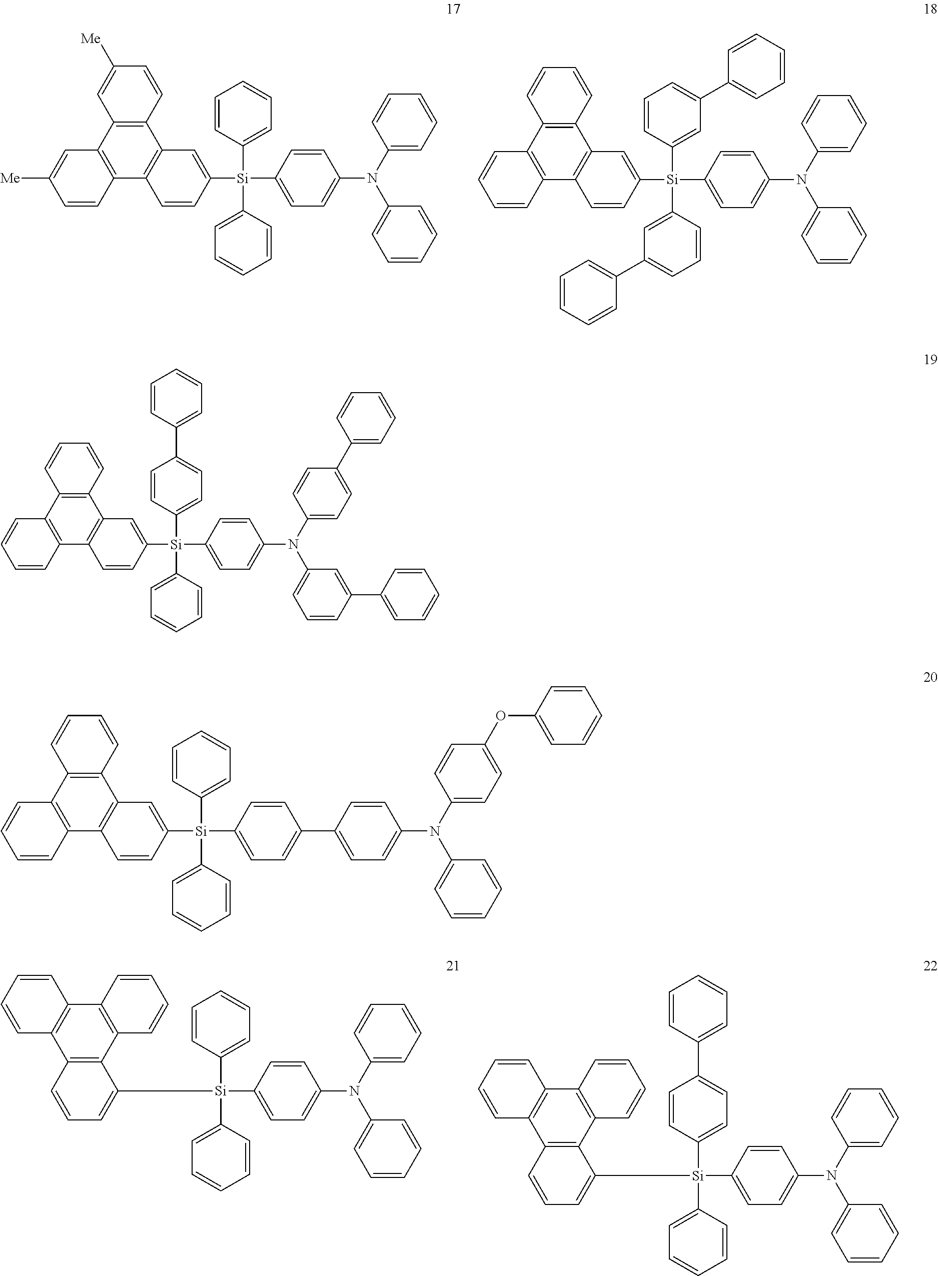

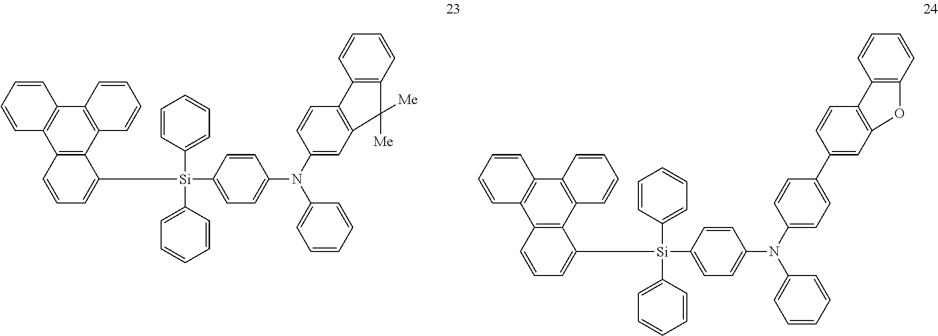 [SMILES: CC1(C)c2ccccc2-c2ccc(N(c3ccccc3)c3ccc([Si](c4ccccc4)(c4ccccc4)c4cccc5c6ccccc6c6ccccc6c45)cc3)cc21 ; c1ccc(N(c2ccc(-c3ccc4c(c3)oc3ccccc34)cc2)c2ccc([Si](c3ccccc3)(c3ccccc3)c3cccc4c5ccccc5c5ccccc5c34)cc2)cc1]

As described above, the silane compound according to an embodiment may include an arylamine group in the molecular structure thereof and may have hole transport properties, so as to be appropriately used as a hole transport material. The silane compound according to an embodiment may have high restraining ability of energy diffusion and may restrain the diffusion of excited energy from an emission layer, such that the emission efficiency of an organic EL device may be improved. In addition, the silane compound according to an embodiment may have high electron tolerance and high electron blocking ability. Accordingly, the deterioration of a hole transport layer due to electrons that may intrude into the hole transport layer may be prevented, and the diffusion of electrons into a hole injection layer may be prevented. Accordingly, the device life of an organic EL device may be improved by the silane compound according to an embodiment.

As described above, the silane compound according to an embodiment may be used as a material of a hole transport layer adjacent to an emission layer. When the silane compound according to an embodiment is used in a hole injection layer or an emission layer, the emission efficiency and device life of an organic EL device may also be improved, as in the case of using the material as a hole transport layer.

1.2 Synthetic Method of Silane Compound

Hereinafter, a synthetic method of a silane compound according to an embodiment will be explained.

Silane compound F according to an embodiment may be synthesized by a general synthetic method represented by the following Reaction 1.

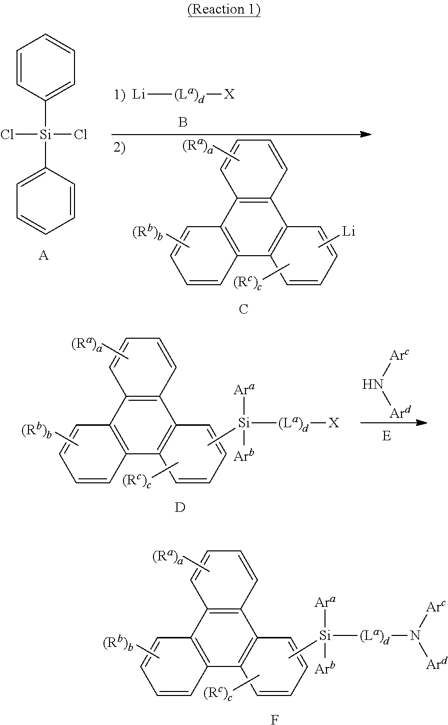

As shown in Reaction 1, with respect to diphenylchlorosilane A, a compound of B (in which respective terminals of a (L^{a})d part are substituted with a halogen atom X and Li) is applied. Then, in the same vessel, triphenylene derivative C substituted with a Li atom is applied to the reactant to synthesize an intermediate of D. After that, by applying arylamine E with respect to the intermediate of D, a silane compound of F according to an embodiment may be synthesized.

In addition, the above-described synthetic method is only an embodiment, and other suitable synthetic methods of making silane compound according to an embodiment may be used.

2. Organic EL Device According to an Embodiment

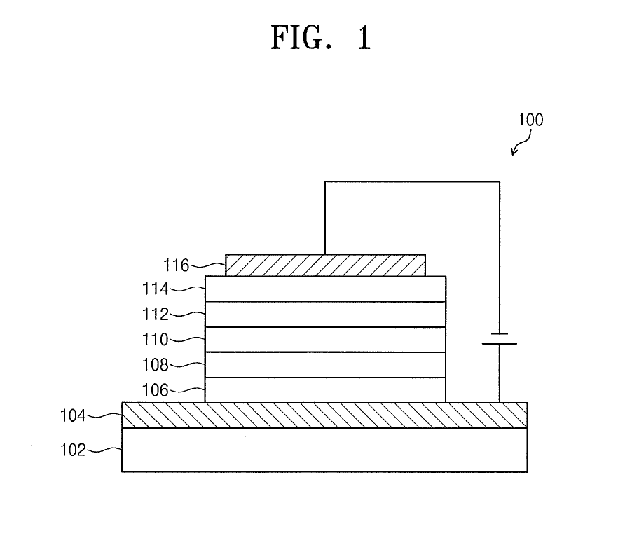

An organic EL device according to an embodiment will be explained with reference to FIG. 1. FIG. 1 is a schematic cross-sectional view of an organic EL device according to an embodiment.

As shown in FIG. 1, the organic EL device 100 according to an embodiment may include a substrate 102, an anode 104 disposed on the substrate 102, a hole injection layer 106 disposed on the anode 104, a hole transport layer 108 disposed on the hole injection layer 106, an emission layer 110 disposed on the hole transport layer 108, an electron transport layer 112 disposed on the emission layer 110, an electron injection layer 114 disposed on the electron transport layer 112 and a cathode 116 disposed on the electron injection layer 114.

In addition, the structure of the organic EL device 100 shown in FIG. 1 is only an embodiment, and the organic EL device may have other suitable structures. For example, the layers of the organic EL device 100 may be partially omitted, and another layer may be added. In addition, each layer of the organic EL device 100 may be formed of a plurality of layers.

The substrate 102 may be, for example, a transparent glass substrate, a semiconductor substrate formed by using silicon (Si), etc., or a flexible substrate of a resin, etc.

The anode 104 may be disposed on the substrate 102 and may be formed by using, for example, a metal having high work function, an alloy, a conductive compound, etc. For example, the anode 104 may be formed using indium tin oxide (ITO), indium zinc oxide (IZO), etc.

The hole injection layer 106 may be disposed on the anode 104 and may include, for example, 4,4′,4″-tris[2-naphthyl(phenyl)amino]triphenylamine (2-TNATA), N,N,N′,N′-tetrakis(3-methylphenyl)-3,3′-dimethylbenzidine (HMTPD), dipyrazino[2,3-f:2′3′-h]quinoxaline-2,3,6,7,10,11-hexacarbonitrile (HAT(CN)₆, etc.

The hole transport layer 108 may disposed on the hole injection layer 106 and may formed by including, for example, N,N′-bis(3-methylphenyl)-N,N′-diphenylbenzidine (TPD), 4,4′,4″-tris(N-carbazolyl)triphenylamine (TCTA), or N,N′-di(1-naphthyl)-N,N′-diphenylbenzidine (NPD).

The emission layer 110 may be disposed on the hole transport layer 108 and may be formed by including a host material and a dopant material. The emission layer 110 may be formed by doping 2,5,8,11-tetra-t-butylperylene (TBP) in a host material including, for example, 9,10-di(2-naphthyl)anthracene (ADN).

At least one organic layer of the hole injection layer 106 and the hole transport layer 108 positioned between the emission layer 110 and the anode 104, or the emission layer 110 may include the silane compound according to an embodiment. By including the silane compound according to an embodiment, the emission efficiency or device life of the organic EL device may be improved.

The electron transport layer 112 may be disposed on the emission layer 110 and may be formed by using, for example, tris(8-hydroxyquinolinato)aluminum (Alq₃), 3-(4-biphenylyl)-4-phenyl-5-(4-tert-butylphenyl)-4H-1,2,4-triazole (TAZ), etc.

The electron injection layer 114 may be disposed on the electron transport layer 112 and may be formed using a material including, for example, lithium fluoride (LiF), sodium chloride (NaCl), cesium fluoride (CsF), lithium oxide (Li₂O), barium oxide (BaO), etc.

The cathode 116 may be disposed on the electron injection layer 114 and may be formed using a metal having low work function, an alloy, a conductive compound, etc. For example, the cathode 116 may be formed by using a metal such as Al or a transparent material such as ITO, IZO, etc.

In the organic EL device 100 shown in FIG. 1, the anode 104, the emission layer 110, the electron transport layer 112, the electron injection layer 114 and the cathode 116 may be formed by using suitable materials for an organic EL device.

Each of the above-described thin layers of the organic EL device 100 according to an embodiment may be formed by selecting an appropriate layer forming method such as vacuum evaporation, sputtering, various coatings, etc.

For example, an electrode layer such as the anode 104 and the cathode 116 may be formed by using an evaporation method including an electron beam evaporation method, a hot filament evaporation method, or a vacuum evaporation method, or a plating method such as an electroplating method or an electroless plating method.

In addition, the organic layer such as the hole injection layer 106, the hole transport layer 108, the emission layer 110, the electron transport layer 112 and the electron injection layer 114 may be formed by a physical vapor deposition (PVD) method such as a vacuum deposition method, a printing method such as a screen printing method or an ink jet printing method, or a coating method such as a laser transfer method or a spin coat method.

As described above, an example of the organic EL device 100 according to an embodiment has been described.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

Hereinafter, a silane compound and an organic EL device according to an embodiment will be particularly explained referring to examples and comparative examples. In addition, the following examples are illustrated as an embodiment of the silane compound and the organic EL device according to an embodiment.

### Synthesis of Silane Compound

First, the silane compound according to an embodiment will be explained referring to synthetic methods of Compounds 1, 9, 11 and 19.

### Synthesis of Compound 1

According to the following Reaction 2, Compound 1 was synthesized as a silane compound according to an embodiment.

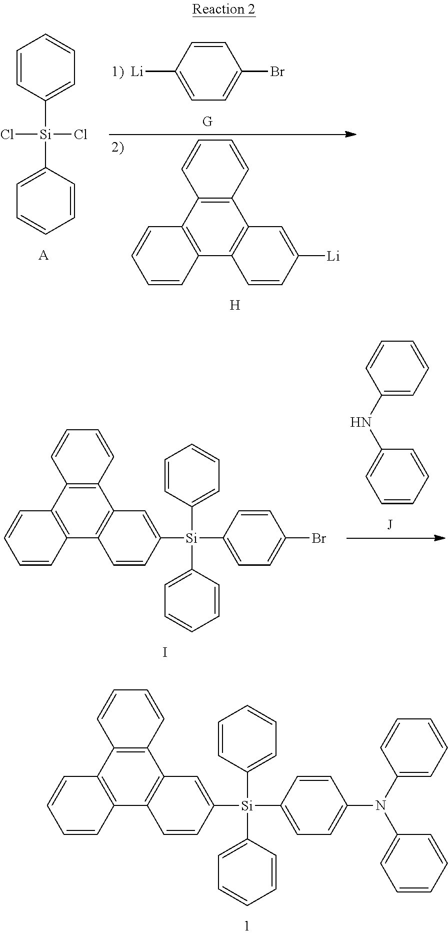

To diphenyldichlorosilane A (5.82 g, 23.0 mmol) in a diethyl ether solution (150 mL), a 4-bromophenyl lithium G solution was added dropwisely at −78° C. In addition, the 4-bromophenyl lithium G solution was controlled by adding a 1.6 M hexane solution of n-butyl lithium (14.4 mL, 23.0 mmol) to a diethyl ether solution (50 mL) of 1,4-dibromobenzene (5.43 g, 23.0 mmol) dropwisely and stirring for 1 hour.

Then, a 2-lithiotriphenylene H solution was added dropwisely at −78° C. to the solution to which the 4-bromophenyl lithium G solution was added dropwisely, followed by stirring for 2 hours. In addition, the 2-lithiotriphenylene H solution was controlled by adding a 1.6 M hexane solution of n-butyl lithium (14.4 mL, 23.0 mmol) to a diethyl ether solution (50 mL) of 2-bromotriphenylene (7.07 g, 23.0 mmol) dropwisely and stirring for 1 hour.

The reaction mixture thus obtained was stirred while elevating the temperature to room temperature, followed by stirring at room temperature for 8 hours further. A small amount of methanol was added to the reaction mixture, followed by stirring for 20 minutes. Then, water was added thereto, and extraction with toluene was performed. The organic layer thus extracted was dried with anhydrous magnesium sulfate, concentrated, and the residue thus obtained was separated by column chromatography to produce 2-(4-bromophenyldiphenylsilyl)triphenylene I (8.85 g, 15.6 mmol, yield 68%) as an almost white powder.

2-(4-bromophenyldiphenylsilyl)triphenylene I (5.46 g, 9.70 mmol), diphenylamine J (1.80 g, 10.7 mmol), tris(dibenzylideneacetone)dipalladium(0) chloroform addition product (201 mg, 0.194 mmol (2 mol %)), and sodium-t-butoxide (1.40 g, 14.5 mmol) were mixed in xylene (200 mL), followed by heating and refluxing for 10 hours. Water was added to the reaction mixture, and extraction with toluene was performed. The organic layer thus extracted was dried with anhydrous magnesium sulfate, concentrated, and the residue thus obtained was separated by column chromatography to produce Compound 1 (4.80 g, 7.10 mmol, yield 73%) as an almost white powder.

Synthesis of Compound 9

Compound 9 was synthesized by performing the same procedure described for synthesizing Compound 1 except for replacing the diphenylamine J with an amine compound having a 4-cyano-biphenyl group and a phenyl group bonded to nitrogen.

Synthesis of Compound 11

Compound 11 was synthesized by performing the same procedure described for synthesizing Compound 1 except for replacing the diphenylamine J with an amine compound having a dibenzofuran group and a phenyl group bonded to nitrogen.

Synthesis of Compound 18

Compound 18 was synthesized by performing the same procedure described for synthesizing Compound 1 except for changing the substituent of the phenyl group in diphenyldichlorosilane A to a biphenyl group.

Manufacture of Organic EL Device

Organic EL devices according to exemplary embodiments were manufactured by a vacuum deposition method and the following procedure.

### Example 1

First, after patterning and washing, an ITO-glass substrate was surface treated with ozone. The thickness of an ITO layer in the glass substrate was about 150 nm. After treating with ozone, a layer was formed using 2-TNATA as a hole injection material on the ITO layer to a thickness of about 60 nm.

After that, a layer was formed using the above Compound A (about 30 nm) as a hole transport material to obtain a hole transport layer (HTL). A layer was formed by co-depositing β-ADN doped with TBP in a ratio of 3% as an emission material (a layer thickness of about 25 nm).

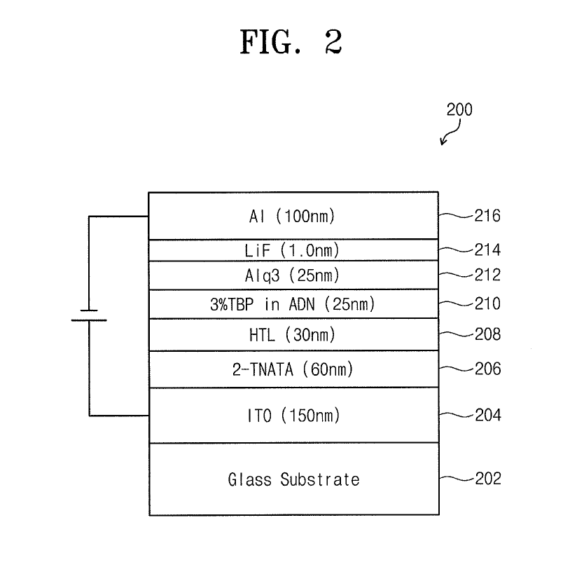

Then, a layer was formed using Alq3 as an electron transport material to a layer thickness of about 25 nm. A layer was formed using LiF as an electron injection material to a layer thickness of about 1.0 nm, and a layer was formed using aluminum (Al) as a cathode to a layer thickness of about 100 nm to manufacture an organic EL device 200 as illustrated in FIG. 2.

### Example 2

An organic EL device was manufactured by performing the same procedure described in Example 1 except for using Compound 9 instead of Compound 1.

### Example 3

An organic EL device was manufactured by performing the same procedure described in Example 1 except for using Compound 11 instead of Compound 1.

### Example 4

An organic EL device was manufactured by performing the same procedure described in Example 1 except for using Compound 18 instead of Compound 1.

### Comparative Example 1

An organic EL device was manufactured by performing the same procedure described in Example 1 except for using the following Compound c1 instead of Compound 1. Compound c1 is different from the silane compound according to an embodiment in having a structure in which one covalent bond forming a triphenylene skeleton is cleaved from Compound 1.

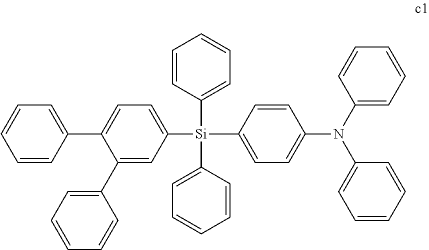 [SMILES: c1ccc(-c2ccc([Si](c3ccccc3)(c3ccccc3)c3ccc(N(c4ccccc4)c4ccccc4)cc3)cc2-c2ccccc2)cc1]

### Comparative Example 2

An organic EL device was manufactured by performing the same procedure described in Example 1 except for using the following Compound c2 instead of Compound 1. Compound c2 is different from the silane compound according to an embodiment in that an amine group is not included in Compound 1.

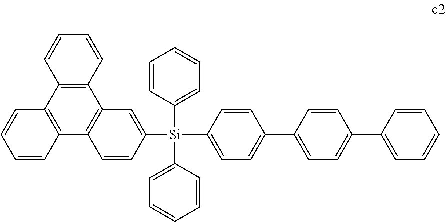 [SMILES: c1ccc(-c2ccc(-c3ccc([Si](c4ccccc4)(c4ccccc4)c4ccc5c6ccccc6c6ccccc6c5c4)cc3)cc2)cc1]

### Comparative Example 3

An organic EL device was manufactured by performing the same procedure described in Example 1 except for using the following Compound c3 instead of Compound 1. Compound c3 is different from the silane compound according to an embodiment in that a covalent bond is formed between Ar^{c} and Ar^{a}, such that an amine structure is substituted with a carbazole ring structure in Compound 1.

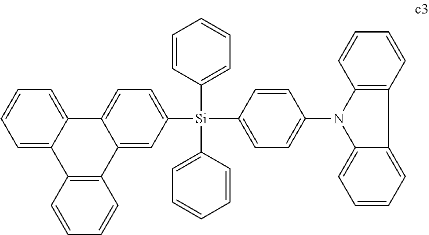 [SMILES: c1ccc([Si](c2ccccc2)(c2ccc(-n3c4ccccc4c4ccccc43)cc2)c2ccc3c4ccccc4c4ccccc4c3c2)cc1]

### Comparative Example 4

An organic EL device was manufactured by performing the same procedure described in Example 1 except for using the following Compound c4 instead of Compound 1. Compound c4 is N,N′-di(1-naphthyl)-N,N′-diphenylbenzidine (a-NPD) and is a common hole transport material.

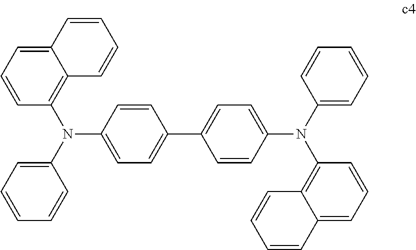 [SMILES: c1ccc(N(c2ccc(-c3ccc(N(c4ccccc4)c4cccc5ccccc45)cc3)cc2)c2cccc3ccccc23)cc1]

A schematic diagram of an organic EL device 200 manufactured in Examples 1 to 4 and Comparative Examples 1 to 4 is illustrated in FIG. 2. The organic EL device 200 thus manufactured includes, a substrate 202, an anode 204 disposed on the substrate 202, a hole injection layer 206 disposed on the anode 204, a hole transport layer 208 disposed on the hole injection layer 206, an emission layer 210 disposed on the hole transport layer 208, an electron transport layer 212 disposed on the emission layer 210, an electron injection layer 214 disposed on the electron transport layer 212 and a cathode 216 disposed on the electron injection layer 214.

Evaluation Results

The evaluation results of the organic EL devices 200 manufactured in Examples 1 to 4 and Comparative Examples 1 to 4 are illustrated in the following Table 1. In addition, for the evaluation of the emission properties of the organic EL devices 200 thus manufactured, a C9920-11 brightness light distribution characteristics measurement system of HAMAMATSU Photonics Co. was used. The evaluation was performed with current density of 10 mA/cm², and half life was measured at 1,000 cd/m².

TABLE 1

| | Hole | Current | | Emission | |
|---|---|---|---|---|---|
| | transport | density | Voltage | efficiency | Life |
| | materials | (mA/cm²) | (V) | (cd/A) | (LT₅₀[h]) |
| Example 1 | Compound | 10 | 8.6 | 6.8 | 2,300 |
| | 1 | | | | |
| Example 2 | Compound | 10 | 8.8 | 6.8 | 1,700 |
| | 9 | | | | |
| Example 3 | Compound | 10 | 8.8 | 6.9 | 2,000 |
| | 11 | | | | |
| Example 4 | Compound | 10 | 8.5 | 6.5 | 1,800 |
| | 18 | | | | |
| Comparative | Compound | 10 | 9.5 | 5.9 | 900 |
| Example 1 | c1 | | | | |
| Comparative | Compound | 10 | 10.1 | 4.3 | 900 |
| Example 2 | c2 | | | | |
| Comparative | Compound | 10 | 8.8 | 5.5 | 700 |
| Example 3 | c3 | | | | |
| Comparative | Compound | 10 | 8.1 | 5.3 | 1,200 |
| Example 4 | c4 | | | | |

Referring to Table 1, the organic EL devices using Compounds 1, 9, 11 and 18, which are the silane compounds according to the embodiments, as hole transport materials according to Examples 1 to 4 were found to have improved emission efficiency and device life when compared to those according to Comparative Examples 1 to 4.

Particularly, the organic EL devices using Compounds 1, 9, 11 and 18, as hole transport materials according to Examples 1 to 4 were found to have a markedly increased device life when compared to the organic EL device according to Comparative Example 1 using Compound c1 having a structure in which one covalent bond forming a triphenylene skeleton is cleaved. In addition, the organic EL devices of Examples 1 to 4 were found to have decreased driving voltage and markedly improved emission efficiency and device life when compared to the organic EL device of Comparative Example 2 using Compound c2 not including an amine structure. In addition, the organic EL devices of Examples 1 to 4 were found to have almost equal driving voltage and markedly improved device life when compared to the EL device of Comparative Example 3 using Compound c3 in which an amine structure is substituted with a carbazole ring structure. In addition, the organic EL devices of Examples 1 to 4 were found to have a not much increased driving voltage and improved emission efficiency and device life when compared to the organic EL device of Comparative Example 4 using Compound c4, which is a common hole transport material.

As shown from the above results, when a silane compound according to an embodiment having a triphenylene skeleton having high planarity and an amine structure having high hole transport ability is used as a hole transport material in an organic EL device, the emission efficiency and device life thereof may be improved without increasing the driving voltage.

In the above-described examples, organic EL devices using the silane compounds according to embodiments as the hole transport materials have been explained. In other implementations, the silane compound according to an embodiment may also be used in other light-emitting devices or light-emitting apparatuses. The organic EL device shown in FIGS. 1 and 2 may be used in an organic EL display of an active-matrix driving type as well as an organic EL display of a passive-matrix driving type.

By way of summation and review, an organic EL device generally has a stacked configuration of an emission layer and another layers such as a hole transport layer and an electron transport layer for transporting holes or electrons and having different properties. In a general organic EL device, various compounds have been examined as the materials of each layer to improve emission properties and realize long life.

For example, an organic silane compound having a triphenylene skeleton may be used as a phosphorescent host compound of an emission layer.

However, the emission efficiency or life of an organic EL device using the phosphorescent host compound may be insufficient. Thus, a compound of a material capable of further improving the emission efficiency or life of the organic EL device is desirable.

The present disclosure in consideration of the above-described defects provides a silane compound capable of improving the emission efficiency or life of an organic EL device, and an organic EL device using the silane compound.

In particular, upon close examination regarding compounds included in an organic layer positioned between an emission layer and an anode of an organic EL device to improve the emission properties or device life of an organic EL device following knowledge has been obtained.

Particularly, it has been found that the emission efficiency or device life of an organic EL device may be greatly improved when a compound having the following properties (1) to (3) is included in the organic layer positioned between an emission layer and an anode of the organic EL device:

(1) A high restraining ability of the diffusion of energy with respect to excited energy generated in an emission layer and the ability to prevent or hinder the diffusion of the excited energy to an adjacent layer.

(2) A high electron tolerance with respect to electrons that intrude from an emission layer to an organic layer and resistance to deterioration.

(3) A high electron blocking ability with respect to electrons that intrude from an emission layer to an organic layer and the ability to prevent or hinder the transfer of the electrons toward an anode.

Embodiments provide a silane compound capable of improving the emission efficiency or life of an organic EL device, and an organic EL device using the silane compound. Accordingly to an embodiment, an organic EL device includes the silane compound in at least one layer of organic layers disposed between an anode and an emission layer to address the above-described tasks. The emission efficiency and life of the organic EL device may be improved by using the silane compound having high restraining ability of the diffusion of excited energy, high electron tolerance and high electron blocking ability.

In another embodiment, an organic EL device includes the silane compound in an emission layer to address the above-described tasks. The emission efficiency and life of the organic EL device may be improved because the silane compound has high restraining ability of the diffusion of excited energy and high electron tolerance.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope thereof as set forth in the following claims.

What is claimed is:

1. A silane compound represented by the following Formula 1: 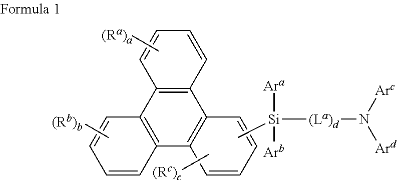
wherein, in the above Formula 1,
R^{a} to R^{c} are independently a substituted or unsubstituted alkyl group having 1 to 12 carbon atoms or a substituted or unsubstituted aryl group having 4 to 18 carbon atoms,
Ar^{a} to Ar^{d} are independently a substituted or unsubstituted aryl group having 6 to 18 carbon atoms or a substituted or unsubstituted heteroaryl group having 5 to 18 carbon atoms,
L^{a} is a substituted or unsubstituted arylene group having 6 to 18 carbon atoms,
a and b as subscripts of R^{a} and R^{b}, respectively, are independently an integer from 0 to 4, and
c and d as subscripts of R^{c} and L^{a}, respectively, are independently an integer from 0 to 3.

2. The silane compound as claimed in claim 1, wherein Ar^{a} and Ar^{b} are independently a substituted or unsubstituted aryl group having 6 to 13 carbon atoms.

3. The silane compound as claimed in claim 1, wherein Ar^{a} and Ar^{b} are independently a substituent selected from a phenyl group, a naphthalenyl group and a biphenylyl group.

4. The silane compound as claimed in claim 1, wherein:
d as a subscript of L^{a} is 0 or 1, and
L^{a} is a substituted or unsubstituted aryl group having 6 to 13 carbon atoms.

5. The silane compound as claimed in claim 1, wherein:
a to c as subscripts of R^{a} to R^{c}, respectively, are 0 or 1, and
R^{a} to R^{c} are independently a substituted or unsubstituted alkyl group having 1 to 6 carbon atoms or a substituted or unsubstituted aryl group having 4 to 12 carbon atoms.

6. The silane compound as claimed in claim 1, wherein the silane compound is at least one represented by the following Compounds 1 to 24:

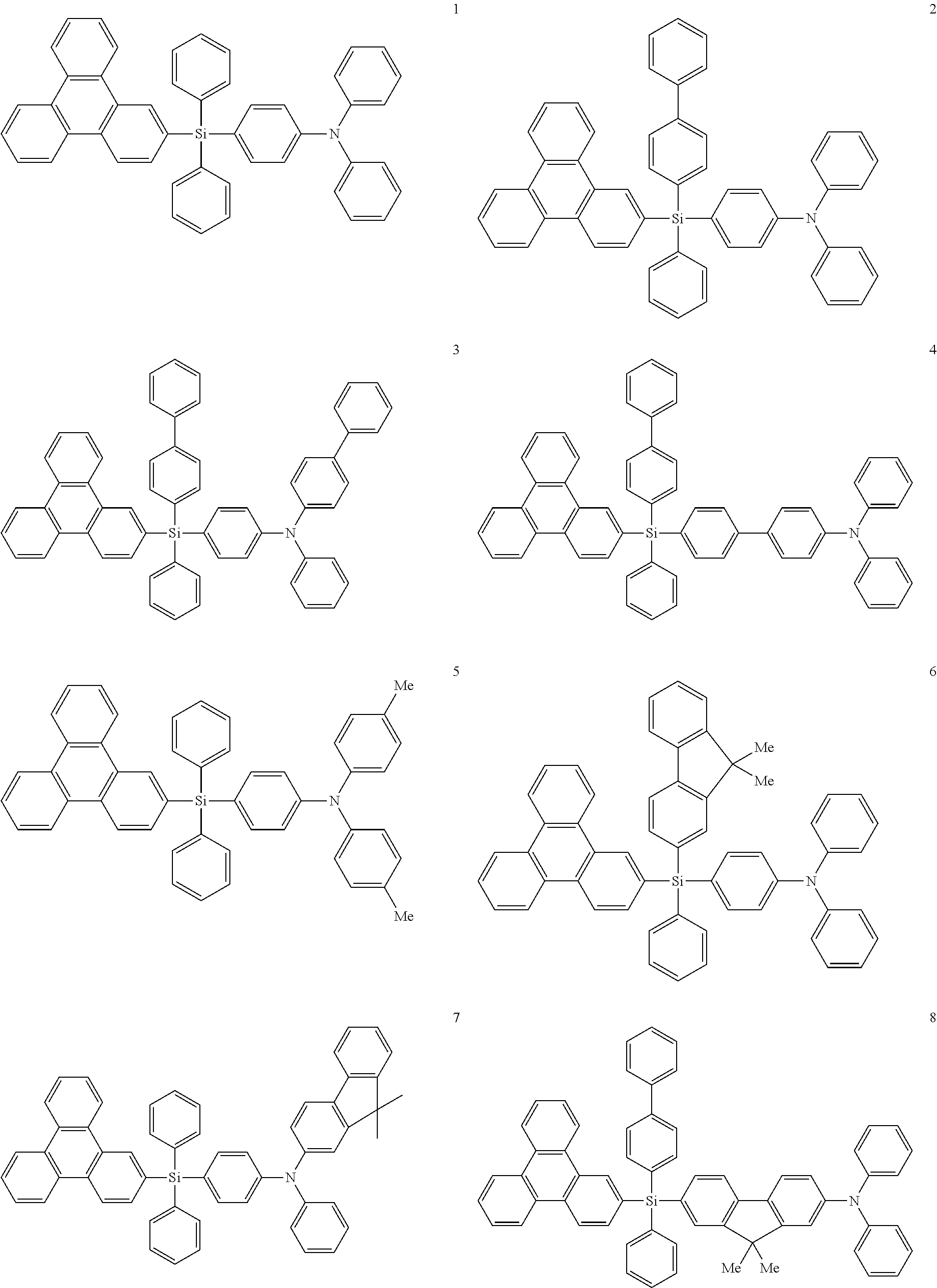

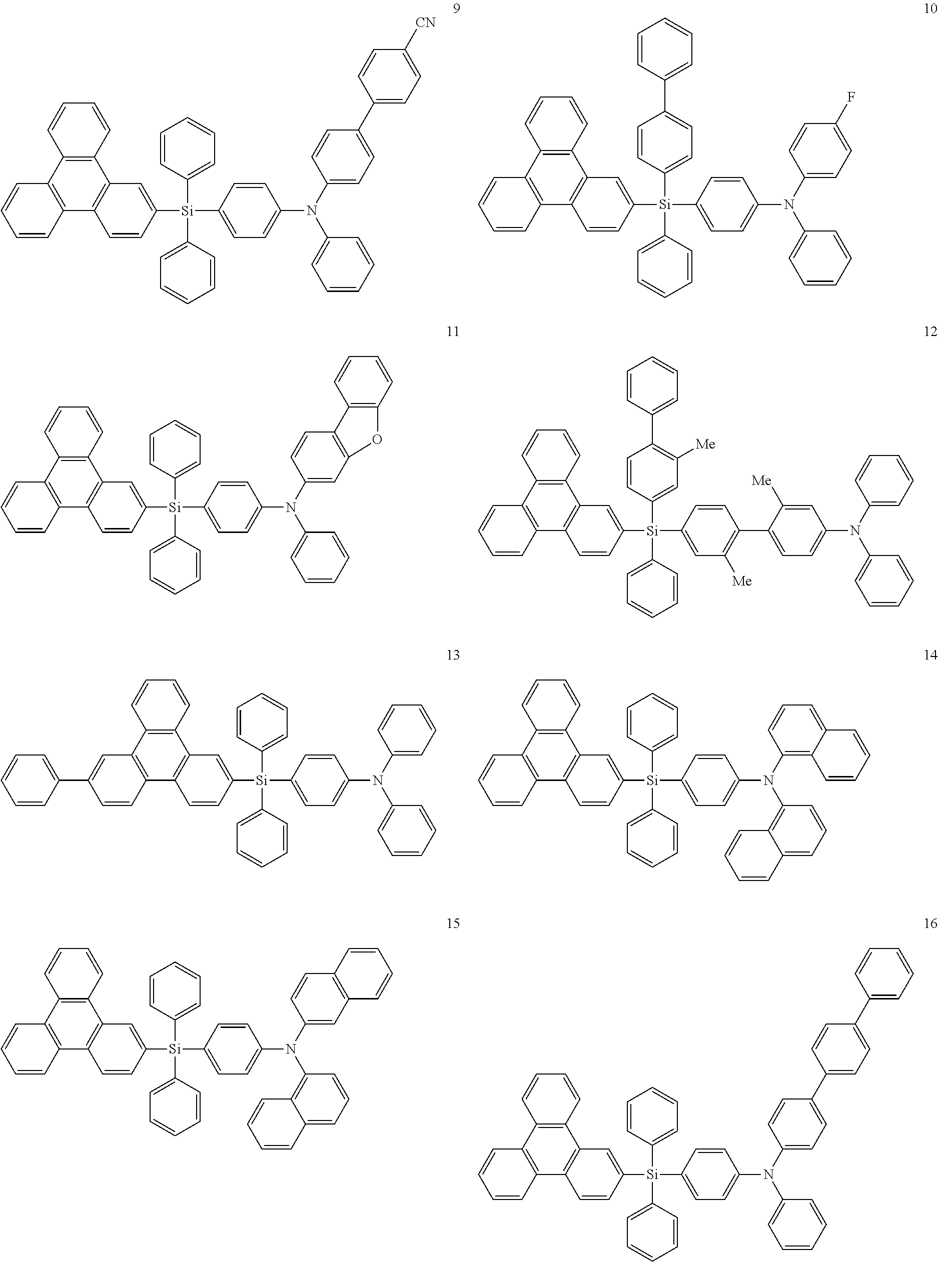

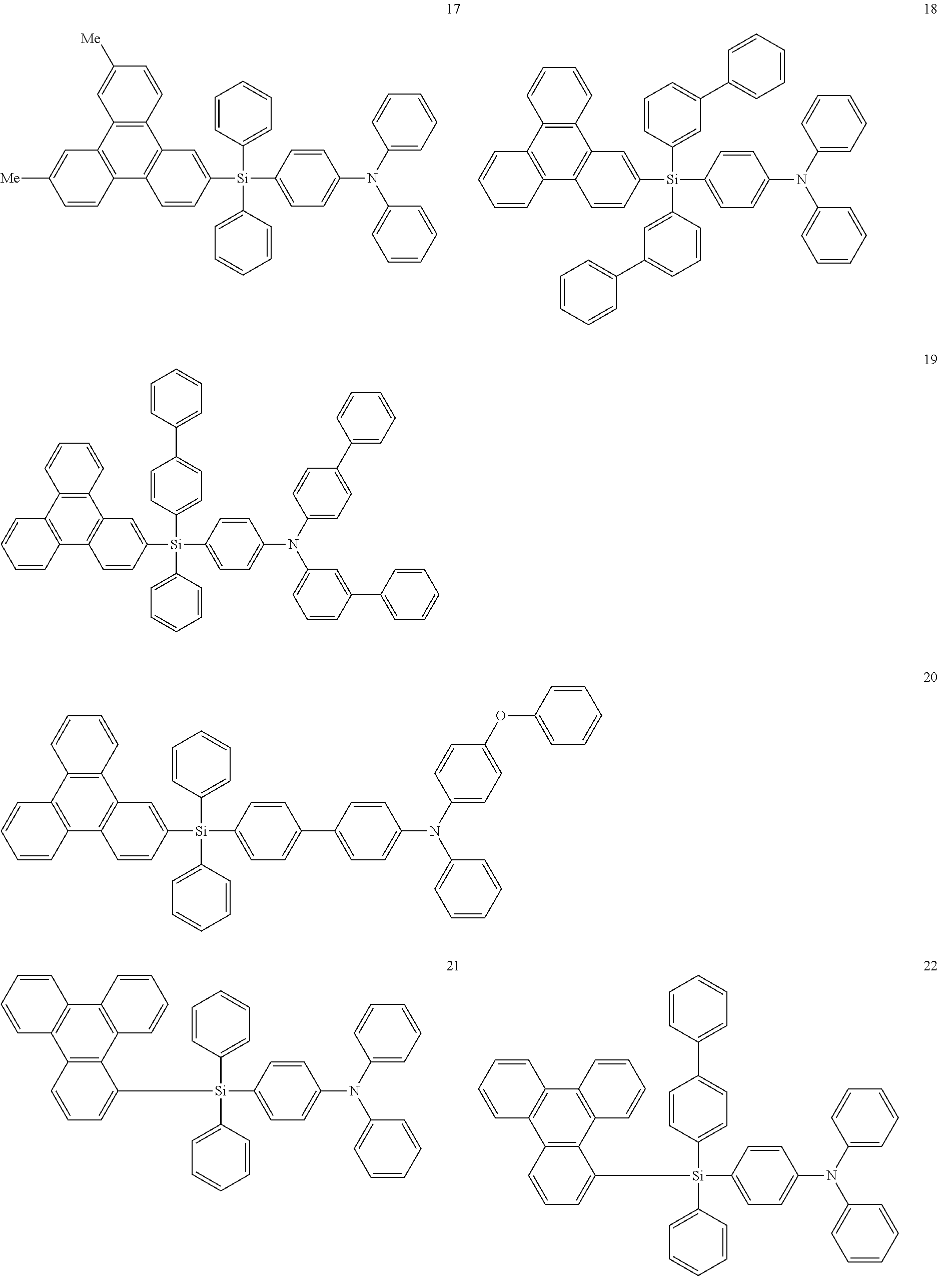

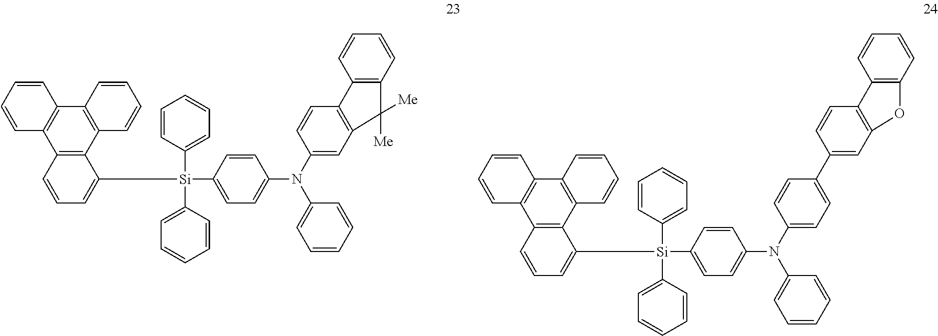 [SMILES: CC1(C)c2ccccc2-c2ccc(N(c3ccccc3)c3ccc([Si](c4ccccc4)(c4ccccc4)c4cccc5c6ccccc6c6ccccc6c45)cc3)cc21 ; c1ccc(N(c2ccc(-c3ccc4c(c3)oc3ccccc34)cc2)c2ccc([Si](c3ccccc3)(c3ccccc3)c3cccc4c5ccccc5c5ccccc5c34)cc2)cc1]

7. The silane compound as claimed in claim 1, wherein at least one hydrogen of the silane compound is substituted with one of a methoxy group, a phenoxy group, a cyano group, a trifluoromethyl group and a fluoro group.

8. An organic electroluminescence (EL) device comprising a silane compound in at least one of a layer among organic layers between an anode and an emission layer, and the emission layer,
the silane compound being represented by the following Formula 1: 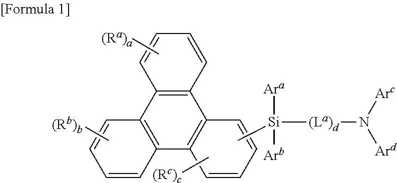
wherein, in the above Formula 1,
R^{a} to R^{c} are independently a substituted or unsubstituted alkyl group having 1 to 12 carbon atoms or a substituted or unsubstituted aryl group having 4 to 18 carbon atoms,
Ar^{a} to Ar^{d} are independently a substituted or unsubstituted aryl group having 6 to 18 carbon atoms or a substituted or unsubstituted heteroaryl group having 5 to 18 carbon atoms,
L^{a} is a substituted or unsubstituted arylene group having 6 to 18 carbon atoms,
a and b as subscripts of R^{a} and R^{b}, respectively, are independently an integer from 0 to 4, and
c and d as subscripts of R^{c} and L^{a}, respectively, are independently an integer from 0 to 3.

9. The organic EL device as claimed in claim 8, wherein Ar^{a} and Ar^{b} are independently a substituted or unsubstituted aryl group having 6 to 13 carbon atoms.

10. The organic EL device as claimed in claim 8, wherein Ar^{a} and Ar^{b} are independently a substituent selected from a phenyl group, a naphthalenyl group and a biphenylyl group.

11. The organic EL device as claimed in claim 8, wherein:
d as a subscript of L^{a} is 0 or 1, and
L^{a} is a substituted or unsubstituted aryl group having 6 to 13 carbon atoms.

12. The organic EL device as claimed in claim 8, wherein:
a to c as subscripts of R^{a} to R^{c}, respectively, are 0 or 1, and
R^{a} to R^{c} are independently a substituted or unsubstituted alkyl group having 1 to 6 carbon atoms or a substituted or unsubstituted aryl group having 4 to 12 carbon atoms.

13. The organic EL device as claimed in claim 8, wherein the silane compound is represented by at least one of the following Compounds 1 to 24:

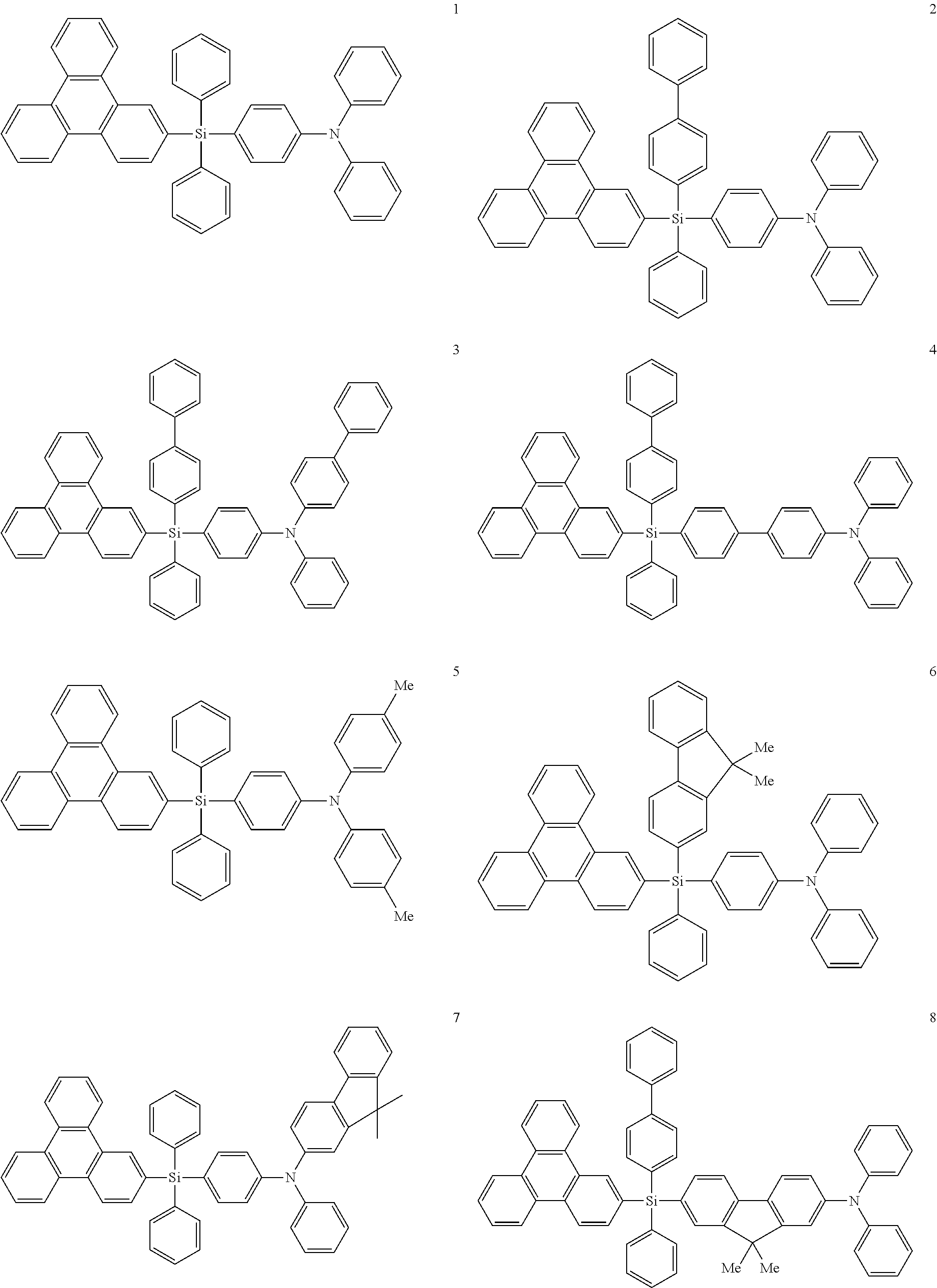

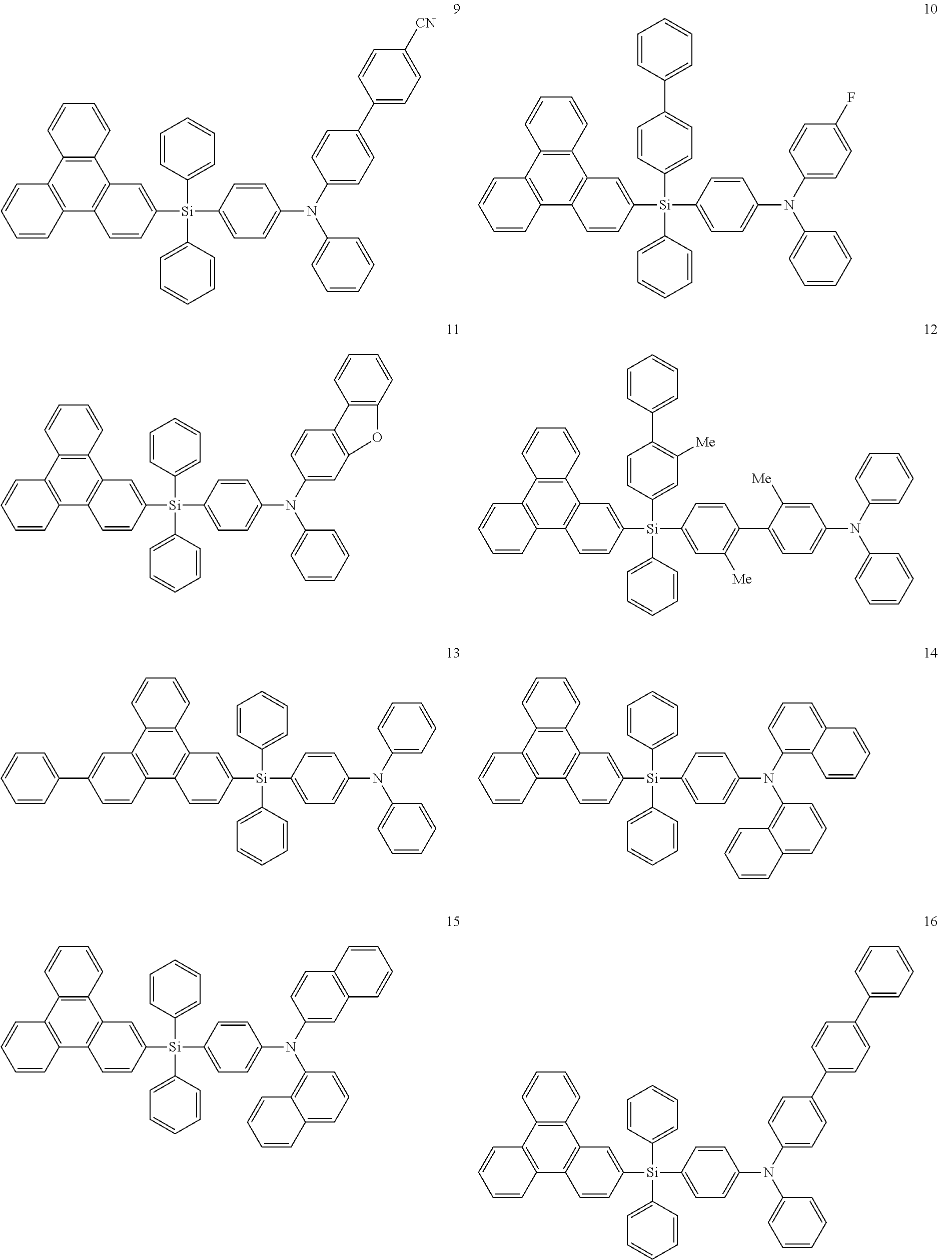

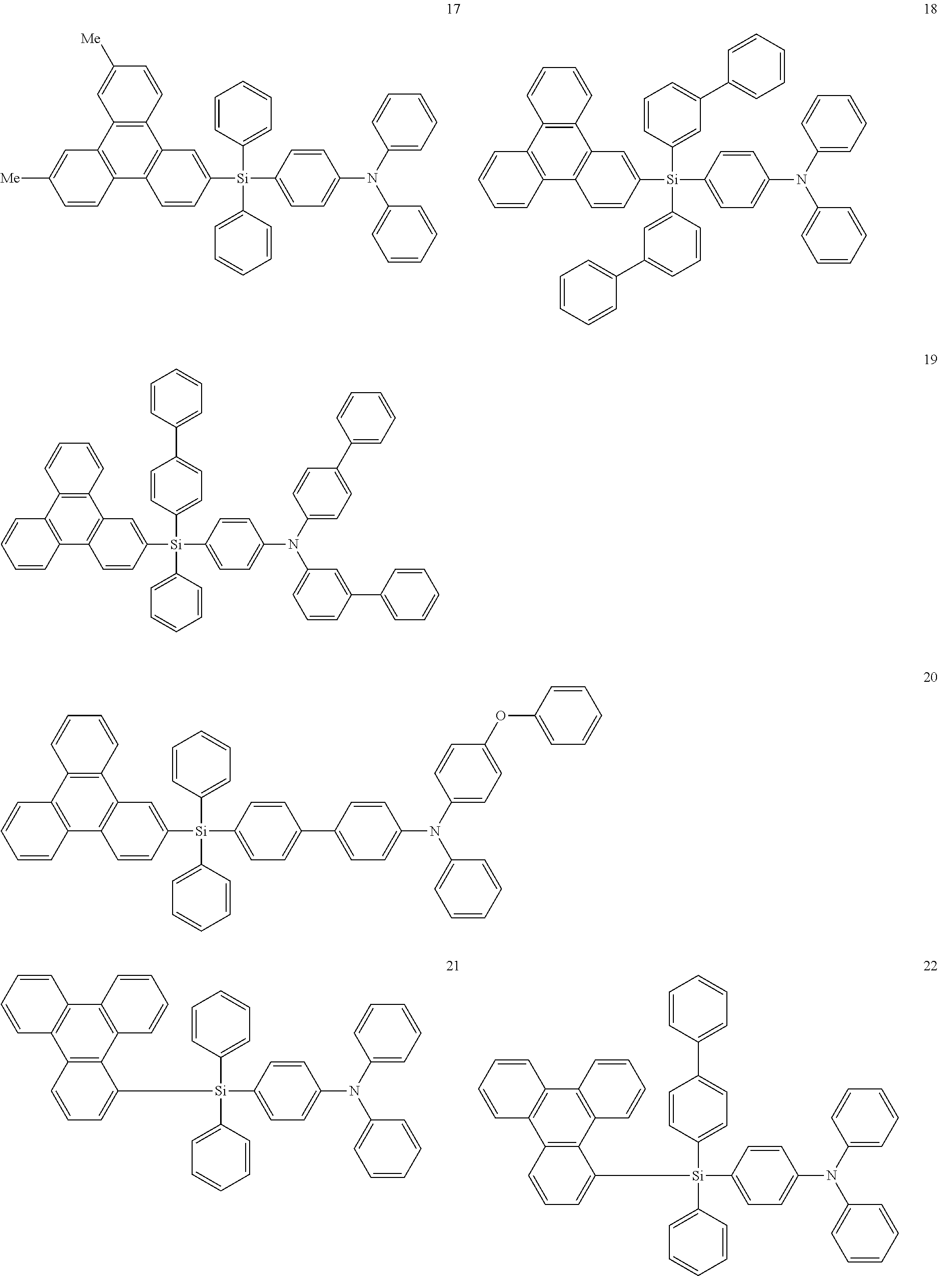

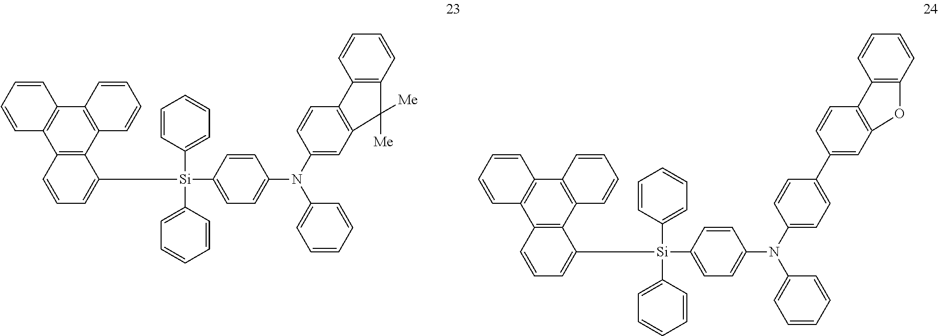 [SMILES: CC1(C)c2ccccc2-c2ccc(N(c3ccccc3)c3ccc([Si](c4ccccc4)(c4ccccc4)c4cccc5c6ccccc6c6ccccc6c45)cc3)cc21 ; c1ccc(N(c2ccc(-c3ccc4c(c3)oc3ccccc34)cc2)c2ccc([Si](c3ccccc3)(c3ccccc3)c3cccc4c5ccccc5c5ccccc5c34)cc2)cc1]

14. The organic EL device as claimed in claim 8, wherein at least one hydrogen of the silane compound is substituted with one of a methoxy group, a phenoxy group, a cyano group, a trifluoromethyl group and a fluoro group.
